(19) United States
(12) Patent Application Publication
(10) Pub. No.: US 2025/0004372 A1
(43) Pub. Date: Jan. 2, 2025

(54) BLOCK COPOLYMER

(71) Applicant: TOKYO OHKA KOGYO CO., LTD., Kawasaki-shi (JP)

(72) Inventor: Kazuaki Ebisawa, Kawasaki-shi (JP)

(21) Appl. No.: 18/698,753

(22) PCT Filed: Sep. 6, 2022
(86) PCT No.: PCT/JP2022/033381

§ 371 Date: Apr. 4, 2024

(30) Foreign Application Priority Data
Oct. 5, 2021 (JP) 2021-164194

(51) Int. Cl. G03F 7/038; C08G 81/02; G03F 7/16

(52) U.S. Cl. CPC G03F 7/0388; C08G 81/024; G03F 7/168

(57) ABSTRACT

A block copolymer which has a small dielectric loss tangent and excellent mechanical properties including elongation and strength; a polyimide resin which is produced by imidizing the block copolymer; a composition from which a resin film containing the block copolymer can be formed; and a method for producing a resin film using the composition. The block copolymer contains a block derived from a polyamide macromonomer and/or a block derived from a polyimide macromonomer, in which the block is produced by the copolymerization of a macromonomer that is a polyamide macromonomer and/or a polyimide macromonomer; a tetracarboxylic acid dianhydride and/or a dicarboxylic acid that is a reaction product of a tetracarboxylic acid dianhydride with an alcohol; and a diamine compound. In the block copolymer, the weight average molecular weight of the block is 1,500 to 30,000 inclusive.

### TECHNICAL FIELD

The present invention relates to a block copolymer including a block derived from a polyimide macromonomer and/or a block derived from a polyamide macromonomer. The present invention also relates to a polyimide resin resulting from imidization of the block copolymer and to a resin film-forming composition including the block copolymer. The present invention further relates to a method of producing a resin film using the resin film-forming composition.

### BACKGROUND ART

Polyimide resins and polyamide resins are widely used as insulating or protective materials for a variety of devices and electric and electronic parts such as electronic boards including multilayer wiring boards as they have high heat resistance, high mechanical strength, high insulation properties, low permittivity, and other favorable properties.

In recent years, communication devices, such as cell phones, have operated at higher frequencies. Thus, insulation parts for insulating metal wiring in communication devices are also required to address higher frequencies. In this regard, an increase in frequency leads to an increase in transmission loss, which leads to electrical signal attenuation. To address higher frequencies and to provide reduced transmission loss, therefore, resins such as polyimide and polyamide resins should have lower dielectric loss tangent and lower permittivity in a high-frequency range.

For such requirements, some compositions that can form resin films exhibiting good dielectric properties in a high frequency range have been proposed, including a photosensitive resin composition including: an aromatic polyamide resin of a specific structure having a structural unit derived from 4,4′-bis(4-aminophenoxy)biphenyl; and a photopolymeriztion initiator (see Examples in Patent Document 1) and a photosensitive resin composition including: a polyimide precursor having an unsaturated double bond-containing side chain; and a photopolymeriztion initiator having an oxime structure capable of generating a specific amount of radicals (see Patent Document 2).

### CITATION LIST

### Patent Document

Patent Document 1: PCT International Publication No. WO2019/044874
Patent Document 2: PCT International Publication No. WO2021/020463

### DISCLOSURE OF THE INVENTION

### Problems to be Solved by the Invention

The photosensitive resin composition described in Patent Document 1 or 2 can form polyimide resin films having a certain low level of dielectric loss tangent. On the other hand, the photosensitive resin composition described in Patent Document 1 or 2 has difficulty in forming resin films with good mechanical properties, such as high elongation and high strength.

It is an object of the present invention, which has been made in view of the problem described above, to provide a block copolymer having low dielectric loss tangent and good mechanical properties, such as high elongation and high strength, to provide a polyimide resin resulting from imidization of such a block copolymer, to provide a resin film-forming composition useful for forming a resin film including such a block copolymer, and to provide a method of producing a resin film using such a resin film-forming composition.

### Means for Solving the Problems

The inventor has created a block copolymer including a copolymer resulting from copolymerization of: a macromonomer being a polyamide macromonomer and/or a polyimide macromonomer; a tetracarboxylic dianhydride and/or a dicarboxylic acid resulting from reaction of a tetracarboxylic dianhydride with an alcohol; and a diamine compound and including: a block derived from the polyamide macromonomer; and/or a block derived from the polyimide macromonomer, in which the block derived from the polyamide macromonomer and/or the block derived from the polyimide macromonomer has a weight average molecular weight of 1,500 or more and 30,000 or less. The inventor has completed the present invention based on findings that such a block copolymer provides a solution to the problem described above. More specifically, the present invention provides the following aspects.

A first aspect of the present invention is directed to a block copolymer including a copolymer resulting from copolymerization of: a macromonomer being a polyamide macromonomer and/or a polyimide macromonomer; a tetracarboxylic dianhydride and/or a dicarboxylic acid resulting from reaction of a tetracarboxylic dianhydride with an alcohol; and a diamine compound,

the block copolymer including: a block derived from the polyamide macromonomer; and/or a block derived from the polyimide macromonomer,
the polyamide macromonomer being a macromonomer resulting from polymerization of a diamine compound and a dicarboxylic acid resulting from reaction of a tetracarboxylic dianhydride with an alcohol,
the polyimide macromonomer being a polyamic acid macromonomer resulting from polymerization of a tetracarboxylic dianhydride and a diamine compound or being a macromonomer resulting from imidization of the polyamide macromonomer,
the polyamide macromonomer and the polyimide macromonomer each having a weight average molecular weight of 1,500 or more and 30,000 or less.

A second aspect of the present invention is directed to a polyimide resin including a product resulting from imidization of the block copolymer according to the first aspect.

A third aspect of the present invention is directed to a resin film-forming composition including: a resin (A); and a solvent (S),

the resin (A) including the block copolymer according to the first aspect and/or the polyimide resin according to the second aspect.

A fourth aspect of the present invention is directed to a resin film forming method including:

applying the resin film-forming composition according to the third aspect onto a substrate to form a coating; and drying the coating to form a resin film.

A fifth aspect of the present invention is directed to a method of forming a patterned resin film, the method including:

applying the resin film-forming composition according to the third aspect onto a substrate to form a coating;
subjecting the coating to positionally selective exposure to an active ray or a radiation; and
developing the exposed coating to form a patterned resin film, wherein in the resin film-forming composition,
the macromonomer is the polyamide macromonomer, and
the polyamide macromonomer is a polymer resulting from polymerization of the diamine compound and the dicarboxylic acid resulting from reaction of a tetracarboxylic dianhydride with a radically polymerizable group-containing alcohol, and wherein the resin film-forming composition contains a photo-radical polymerization initiator (C).

### Effects of the Invention

The present invention provides a block copolymer having low dielectric loss tangent and good mechanical properties, such as high elongation and high strength, provides a polyimide resin resulting from imidization of such a block copolymer, provides a resin film-forming composition useful for forming a resin film including such a block copolymer, and provides a method of producing a resin film using such a resin film-forming composition.

### PREFERRED MODE FOR CARRYING OUT THE INVENTION

### <<Block Copolymer>>

The block copolymer is a copolymer resulting from copolymerization of: a macromonomer being a polyamide macromonomer and/or a polyimide macromonomer; a tetracarboxylic dianhydride and/or a dicarboxylic acid resulting from reaction of a tetracarboxylic dianhydride with an alcohol; and a diamine compound. Thus, the block copolymer includes a block derived from the polyamide macromonomer; and/or a block derived from the polyimide macromonomer. The polyamide macromonomer is a macromonomer resulting from polymerization of a diamine compound and a dicarboxylic acid resulting from reaction of a tetracarboxylic dianhydride with an alcohol. The polyimide macromonomer is a polyamic acid macromonomer resulting from polymerization of a tetracarboxylic dianhydride and a diamine compound or is a macromonomer resulting from imidization of the polyamide macromonomer. The polyamide macromonomer and the polyimide macromonomer each have a weight average molecular weight of 1,500 or more and 30,000 or less, preferably 1,500 or more and 25,000 or less, even more preferably 2,500 or more and 25,000 or less. The weight average molecular weight of the polyamide macromonomer and the polyimide macromonomer can be measured as the polystyrene-equivalent weight average molecular weight by GPC (gel permeation chromatography). The block copolymer defined above has low dielectric loss tangent and good mechanical properties, such as high elongation and high strength.

<Polyamide Macromonomer and/or Polyimide Macromonomer>

As mentioned above, the polyamide macromonomer is a macromonomer resulting from polymerization of a diamine compound and a dicarboxylic acid resulting from reaction of a tetracarboxylic dianhydride with an alcohol. The polyimide macromonomer is a polyamic acid macromonomer resulting from polymerization of a tetracarboxylic dianhydride and a diamine compound or is a macromonomer resulting from imidization of the polyamide macromonomer.

The polyamide macromonomer and the polyimide macromonomer each have a weight average molecular weight of 1,500 or more and 30,000 or less. The weight average molecular weight of the polyamide macromonomer or the polyimide macromonomer can be adjusted by controlling the conditions for the polymerization of monomer compounds during the production of the polyamide macromonomer or the polyimide macromonomer. For example, the weight average molecular weight tends to decrease with decreasing polymerization reaction time. The weight average molecular weight tends to increase with increasing polymerization reaction time. The weight average molecular weight of the polyamide macromonomer can also be adjusted by controlling the amounts or proportions of the dicarboxylic acid and the diamine compound during its production, and the weight average molecular weight of the polyimide macromonomer can also be adjusted by controlling the amounts or proportions of the tetracarboxylic dianhydride and the diamine compound during its production. During the production of the macromonomer having amino end groups, the raw material ratio represented by (the number of moles of the dicarboxylic acid or the tetracarboxylic dianhydride)/(the number of moles of the diamine compound) is preferably controlled within the range of 0.5/1 to 0.95/1, more preferably within the range of 0.55/1 to 0.80/1. As the ratio (the number of moles of the dicarboxylic acid or the tetracarboxylic dianhydride)/(the number of moles of the diamine compound) decreases, the macromonomer becomes less likely to extend its molecular chain and more likely to have a low molecular weight. During the production of the macromonomer having dicarboxylic anhydride end groups or carboxy end groups, the raw material ratio represented by (the number of moles of the diamine compound)/(the number of moles of the dicarboxylic acid or the tetracarboxylic dianhydride) is preferably controlled within the range of 0.5/1 to 0.95/1, more preferably within the range of 0.55/1 to 0.80/1. As the ratio (the number of moles of the diamine compound)/(the number of moles of the dicarboxylic acid or the tetracarboxylic dianhydride) decreases, the macromonomer becomes less likely to extend its molecular chain and more likely to have a low molecular weight.

The block copolymer is produced by polymerization of the polyamide macromonomer and/or the polyimide macromonomer with a monomer or monomers selected from the group consisting of a tetracarboxylic dianhydride, a dicarboxylic acid, and a diamine compound, which will be described later. For the polymerization, the polyamide macromonomer and the polyimide macromonomer need to have an end group capable of reacting with the dicarboxylic anhydride group, the carboxy group, or the amino group. Usually, the polyimide macromonomer and the polyamide macromonomer are each linear and have reactive end groups at both ends. The linear polyamide or polyimide macromonomer may have, at both ends, amino groups, dicarboxylic anhydride groups, or dicarboxylic acid groups resulting from ring-opening reaction between water and the dicarboxylic anhydride groups. Alternatively, the linear polyamide or polyimide macromonomer may have an amino group at one end and a dicarboxylic anhydride group at the other end or may have an amino group at one end and a dicarboxylic acid group at the other end resulting from ring-opening reaction between water and the dicarboxylic anhydride group.

In the block copolymer, the content of the structural units derived from the polyamide macromonomer and the polyimide macromonomer is preferably 1 mass % or more and 70 mass % or less, more preferably 5 mass % or more and 50 mass % or less.

Hereinafter, the polyamide macromonomer and the polyimide macromonomer will be described.

### [Polyamide Macromonomer]

The polyamide macromonomer is a macromonomer resulting from polymerization of a diamine compound and a dicarboxylic acid resulting from reaction of a tetracarboxylic dianhydride with an alcohol. The block copolymer may have a block derived from the polyamide macromonomer. The polyamide macromonomer may be a macromonomer resulting from polymerization of one or two or more diamine compounds and one or two or more dicarboxylic acids resulting from reaction of a tetracarboxylic dianhydride(s) with an alcohol(s). The block copolymer may be produced using a single polyamide macromonomer or two or more polyamide macromonomers. Hereinafter, the diamine compound and the dicarboxylic acid resulting from reaction of a tetracarboxylic dianhydride with an alcohol will be described.

### [Diamine Compound]

The diamine compound may be any type used for the production of polyimide resin, polyamic acid, and polyamide resin in the art. The diamine compound is represented by Formula (A2) below. H₂N-A¹-NH₂ (A2)

In Formula (A2), A¹ is a divalent organic group.

A¹ is a divalent organic group. A¹ may be substituted with one or more substituents in addition to the two amino groups. Preferred examples of the substituent include fluorine, alkyl having 1 or more and 6 or less carbon atoms, alkoxy having 1 or more and 6 or less carbon atoms, fluorinated alkyl having 1 or more and 6 or less carbon atoms, fluorinated alkoxy having 1 or more and 6 or less carbon atoms, carboxy, and hydroxy. The fluorinated alkyl substituent or the fluorinated alkoxy substituent is preferably perfluoroalkyl or perfluoroalkoxy.

The number of carbon atoms in the organic group A¹ preferably has a lower limit of 2, more preferably a lower limit of 6. The number of carbon atoms in the organic group A¹ preferably has an upper limit of 50, more preferably an upper limit of 30. A¹ is preferably an organic group containing one or more aromatic rings, while it may be an aliphatic group.

In a case where A¹ is an organic group containing one or more aromatic groups, it may be a single aromatic group itself or a group including two or more aromatic moieties linked via an aliphatic hydrocarbon group, a halogenated aliphatic hydrocarbon group, or a linking moiety containing a heteroatom, such as oxygen, sulfur, or nitrogen. Examples of such a linking moiety containing a heteroatom, such as oxygen, sulfur, or nitrogen, in A¹ include —CONH—, —NH—, —N═N—, —CH═N—, —COO—, —O—, —CO—, —SO—, —SO₂—, —S—, and —S—S—, among which —COO—, —O—, —CO—, and —S— are preferred.

In A¹, the aromatic ring bonded to the amino group is preferably a benzene ring. In A¹, the ring bonded to the amino group may be a fused ring including two or more rings fused together. In such a case, the fused ring preferably contains a benzene ring moiety bonded to the amino group. The aromatic ring in A¹ may also be an aromatic heterocyclic ring.

For the formation of a resin film with improved electric and mechanical properties, the organic group A¹ containing an aromatic ring is preferably at least one selected from the group consisting of organic groups of Formulae (21) to (24) below.

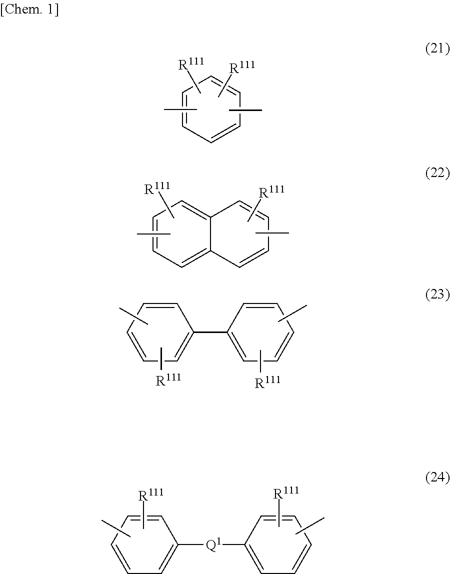

In Formulae (21) to (24), R¹¹¹ is one selected from the group consisting of a hydrogen atom, a fluorine atom, a carboxy group, a sulfonic acid group, a hydroxy group, an alkyl group having 1 or more and 4 or less carbon atoms, and a halogenated alkyl group having 1 or more and 4 or less carbon atoms. In Formula (24), Q¹ is a 9,9′-fluorenylidene group or one selected from the group consisting of the groups: —C₆H₄—, —C₆H₄—C₆H₄—, —O—C₆H₄—C₆H₄—O—, —O—C₆H₄—CO—C₆H₄—O—, —O—C₆H₄—C(CH₃)₂C₆H₄—O—, —OCO—C₆H₄—COO—, —OCO—C₆H₄—C₆H₄—COO—, —OCO—, —O—, —CO—, —C(CF₃)₂—, —C(CH₃)₂—, —CH₂—, —O—C₆H₄—SO₂—C₆H₄—O—, —C(CH₃)₂—C₆H₄—C(CH₃)₂—, —O—C₁₀H₆—O—, —O—C₆H₄—O—, —O—CH₂—O—, —O—(CH₂)₂—O—, —O—(CH₂)₃—O—, —O— (CH₂)₄—O—, —O—(CH₂)₅—O—, and —O— (CH₂)₆—O—.

In the examples of Q¹, —C₆H₄— is a phenylene group, which is preferably m-phenylene or p-phenylene, more preferably p-phenylene. The group —C₁₀H₆— is a naphthalenediyl group, which is preferably naphthalene-1,2-diyl, naphthalene-1,4-diyl, naphthalene-2,3-diyl, naphthalene-2,6-diyl, or naphthalene-2,7-diyl, more preferably naphthalene-1,4-diyl or naphthalene-2,6-diyl.

For the formation of a resin film with improved electrical properties, R¹¹¹ in Formulae (21) to (24) is preferably hydrogen, fluorine, methyl, ethyl, or trifluoromethyl, more preferably hydrogen or trifluoromethyl.

For the formation of a resin film with good electrical and mechanical properties, Q¹ in Formula (24) is preferably —C₆H₄—C₆H₄—, —O—C₆H₄—C₆H₄—O—, —O—C₆H₄—CO—C₆H₄—O—, —O—C₆H₄—C(CH₃)₂—C₆H₄—O—, —OCO—C₆H₄—COO—, —OCO—CsH₄—C₆H₄—COO—, —OCO—, —O—, —CO—, —C(CF₃)₂—, —C(CH₃)₂—, —CH₂—, —O—C₆H₄—SO₂—C₆H₄—O—, —C(CH₃)₂—C₆H₄—C(CH)₂—, —O—C₁₀H₆—O—, —O—C₆H₄—O—, —O—CH₂—O—, —O—(CH₂)₂—O—, —O—(CH₂))—O—, —O—(CH₂)₄—O—, —O—(CH₂)₅—O—, or —O—(CH₂)₆—O—. For improved electrical and mechanical properties of the block copolymer, Q¹ in Formula (24) is more preferably —O—C₆H₄—C₆H₄—O— or —O—C₆H₄—C(CH₃)₂—C₆H₄—O—, even more preferably —O—C₆H₄—C₆H₄—O— in which both —C₆H₄— groups are p-phenylene.

The diamine compound of Formula (A2) may be an aromatic diamine compound. In such a case, the aromatic diamine compound is preferably one or more of those listed below. Examples of the aromatic diamine compound include p-phenylenediamine, m-phenylenediamine, 2,4-diaminotoluene, 4,4′-diaminobiphenyl, 3,3′-diaminobiphenyl, 3,4′-diaminobiphenyl, 1,5-diaminonaphthalene, 2,6-diaminonaphthalene, 9,10-diaminoanthracene, 9,10-bis(4-aminophenyl)anthracene, 4,4′-diamino-2,2′-bis(trifluoromethyl)biphenyl, 4,4′-diaminobenzophenone, 3,3′-diaminobenzophenone, 3,4′-diaminobenzophenone, 4,4′-diaminodiphenyl sulfone, 3,3′-diaminodiphenyl sulfone, 3,4′-diaminodiphenyl sulfone, 4,4′-diaminodiphenyl sulfide, 3,3′-diaminodiphenyl sulfide, 3,4′-diaminodiphenyl sulfide, 4,4′-diaminodiphenylmethane, 3,3′-diaminodiphenylmethane, 3,4′-diaminodiphenylmethane, 2,2-bis(4-aminophenyl)propane, bis(3-amino-4-hydroxyphenyl)methane, 2,2-bis(3-amino-4-hydroxyphenyl)propane, 2,2-bis[4-(4-aminophenoxy)phenyl]propane, 2,2-bis[4-(4-aminophenoxy)phenyl]hexafluoropropane, 2,2′-bis[N-(3-aminobenzoyl)-3-amino-4-hydroxyphenyl]propane, 2,2′-bis[N-(4-aminobenzoyl)-3-amino-4-hydroxyphenyl]propane, 4,4′-diaminodiphenyl ether, 3,4′-diaminodiphenyl ether, 3,3′-diaminodiphenyl ether, 3-carboxy-4,4′-diaminodiphenyl ether, 3-sulfo-4,4′-diaminodiphenyl ether, 4,4′-diaminobenzanilide, 3,3′-diaminobenzanilide, 1,4-bis(4-aminophenyl)benzene, 1,3-bis(4-aminophenyl)benzene, 1,4-bis(4-aminophenoxy)benzene, 1,3-bis(4-aminophenoxy)benzene, 1,3-bis(3-aminophenoxy)benzene, 1,2-bis(4-aminophenoxy)ethane, 1,3-bis(4-aminophenoxy)propane, 1,4-bis(4-aminophenoxy)butane, 1,5-bis(4-aminophenoxy)pentane, 1,6-bis(4-aminophenoxy)hexane, bis(3-amino-4-hydroxyphenyl) ether, bis[4-(4-aminophenoxy)phenyl] ether, bis[4-(3-aminophenoxy)phenyl]ether, 4,4′-bis(4-aminophenoxy)biphenyl, 3,4′-bis(4-aminophenoxy)biphenyl, 3,3′-bis(4-aminophenoxy)biphenyl, bis(3-amino-4-hydroxyphenyl) sulfone, bis(4-aminophenoxyphenyl) sulfone, bis(3-aminophenoxyphenyl) sulfone, bis[4-(4-aminophenoxy)phenyl] sulfone, bis[4-(3-aminophenoxy)phenyl] sulfone, bis[N-(3-aminobenzoyl)-3-amino-4-hydroxyphenyl] sulfone, bis[N-(4-aminobenzoyl)-3-amino-4-hydroxyphenyl] sulfone, bis[4-(4-aminophenoxy)phenyl] ketone, 2,2-bis[4-(4-amino-2-(trifluoromethyl)phenoxy]phenyl]hexafluoropropane, 9,9-bis(4-aminophenyl)fluorene, 9,9-bis(4-amino-3-methylphenyl)fluorene, 9,9-bis(3-amino-4-hydroxyphenyl)fluorene, 9,9-bis[N-(3-aminobenzoyl)-3-amino-4-hydroxyphenyl]fluorene, 9,9-bis[N-(4-aminobenzoyl)-3-amino-4-hydroxyphenyl]fluorene, 2,7-diaminofluorene, 2-(4-aminophenyl)-5-aminobenzoxazole, 2-(3-aminophenyl)-5-aminobenzoxazole, 2-(4-aminophenyl)-6-aminobenzoxazole, 2-(3-aminophenyl)-6-aminobenzoxazole, 1,4-bis(5-amino-2-benzoxazolyl)benzene, 1,4-bis(6-amino-2-benzoxazolyl)benzene, 1,3-bis(5-amino-2-benzoxazolyl)benzene, 1,3-bis(6-amino-2-benzoxazolyl)benzene, 2,6-bis(4-aminophenyl)benzobisoxazole, 2,6-bis(3-aminophenyl)benzobisoxazole, bis[(3-aminophenyl)-5-benzoxazolyl], bis[(4-aminophenyl)-5-benzoxazolyl], bis[(3-aminophenyl)-6-benzoxazolyl], bis[(4-aminophenyl)-6-benzoxazolyl], N,N′-bis(3-aminobenzoyl)-2,5-diamino-1,4-dihydroxybenzene, N,N′-bis(4-aminobenzoyl)-2,5-diamino-1,4-dihydroxybenzene, N,N′-bis(4-aminobenzoyl)-4,4′-diamino-3,3-dihydroxybiphenyl, N,N′-bis(3-aminobenzoyl)-3,3′-diamino-4,4-dihydroxybiphenyl, N,N′-bis(4-aminobenzoyl)-3,3′-diamino-4,4-dihydroxybiphenyl, 3,4′-diaminodiphenyl sulfide, 4,4′-diaminodiphenyl sulfide, 4,4′-[1,4-phenylenebis(1-methylethane-1,1-diyl)]dianiline, 3,5-diaminobenzoic acid, 3,4-diaminobenzoic acid, 4-aminophenyl 4-aminobenzoate, 1,3-bis(4-anilino)tetramethyldisiloxane, 1,4-bis(3-aminopropyldimethylsilyl)benzene, and o-tolidine sulfone. In particular, for improved electric and mechanical properties, the aromatic diamine compound is preferably 4,4′-bis(4-aminophenoxy)biphenyl, 3,4′-bis(4-aminophenoxy)biphenyl, or 3,3′-bis(4-aminophenoxy)biphenyl.

A¹ may also be a silicon atom-containing group optionally having a chain aliphatic group and/or an aromatic ring. Such a silicon atom-containing group may be typically any of the groups listed below.

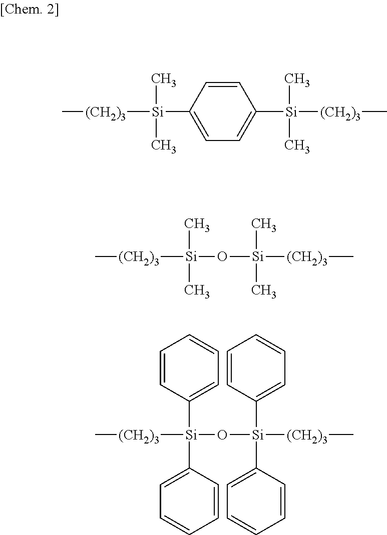

Examples of a compound having amino groups at both ends and a silicon atom-containing group include both terminal amino-modified methylphenylsilicone (e.g., X-22-1660B-3 (about 4,400 in number average molecular weight) and X-22-9409 (about 1,300 in number average molecular weight) manufactured by Shin-Etsu Chemical Co., Ltd.) and both terminal amino-modified dimethylsilicone (e.g., X-22-161A (about 1,600 in number average molecular weight), X-22-161B (about 3,000 in number average molecular weight), and KF8012 (about 4,400 in number average molecular weight) manufactured by Shin-Etsu Chemical Co., Ltd.; BYl6-835U (about 900 in number average molecular weight) manufactured by Toray Dow Corning; and Silaplane FM3311 (about 1,000 in number average molecular weight) manufactured by JNC Corporation).

The diamine compound of Formula (A2) is also preferably an oxyalkylene group-containing diamine. Preferred examples of the oxyalkylene group include ethyleneoxy and propyleneoxy (e.g., —C(CH₃)—CH₂—O—, —CH₂—C(CH₃)—O—, —CH₂CH₂CH₂—O—). The oxyalkylene group-containing diamine may have a combination of two or more oxyalkylene groups. In such a case, the oxyalkylene group-containing diamine may have two or more oxyalkylene groups in a block manner or in a random manner. The oxyalkylene group-containing diamine is preferably free of any cyclic group, more preferably free of any aromatic group. Examples of the oxyalkylene group-containing diamine include Jeffamine® KH-511, Jeffamine® ED-600, Jeffamine® ED-900, Jeffamine® ED-2003, Jeffamine® EDR-148, Jeffamine® EDR-176, Jeffamine® D-200, Jeffamine® D-400, Jeffamine® D-2000, and Jeffamine® D-4000 manufactured by Huntsman, and 1-(2-(2-(2-aminopropoxy)ethoxy)propoxy)propan-2-amine, and 1-(1-(1-(2-aminopropoxy)propan-2-yl)oxy)propan-2-amine.

For high solubility of the block copolymer in organic solvents and for good dielectric properties of the block copolymer in a high frequency range, the diamine compound preferably includes one or more selected from the group consisting of a diamine compound (A-1) of Formula (A1) below, a diamine compound (A-2) having a partial structure of Formula (A2) below and not corresponding to the diamine compound (A-1), a diamine compound (A-3) having a partial structure of Formula (A3) below and not corresponding to the diamine compound (A-1) or (A-2), and a dimer diamine comoound (A-4).

### (Diamine Compound (A-1))

The diamine compound (A-1) is a compound of Formula (A1) below.

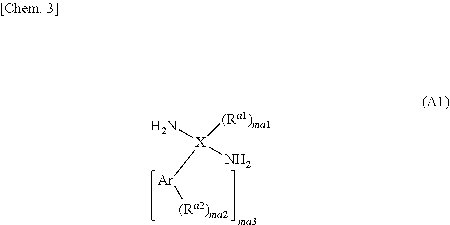

In Formula (A1), X is an organic group having 1 or more and 100 or less carbon atoms,

R^{a1} is a hydroxy group, a carboxy group, or a halogen atom,
R^{a2} is an aliphatic group having 1 or more and 20 or less carbon atoms, a hydroxy group, a carboxy group, a sulfonic acid group, or a halogen atom,
Ar is a phenyl group optionally substituted with R^{a2} or a naphthyl group optionally substituted with R^{a2},
ma1 is an integer of 0 or more and 10 or less,
ma2 is an integer of 0 or more and 7 or less, and
ma3 is an integer of 1 or more and 10 or less.

In Formula (A1), Ar is a phenyl group optionally substituted with R^{a2} or a naphthyl group optionally substituted with R^{a2}. Ar is preferably phenyl or naphthyl. In other words, ma2 in Formula (A1) is preferably 0.

In Formula (A1), R^{a2} is an aliphatic group having 1 or more and 20 or less carbon atoms, a hydroxy group, a carboxy group, a sulfonic acid group, or a halogen atom. When R^{a2} is an organic group, it may contain a heteroatom, such as O, N, S, P, B, Si, or a halogen atom. When R^{a2} is an aliphatic group, it preferably have 1 or more and 12 or less carbon atoms, more preferably 1 or more and 6 or less carbon atoms.

When R^{a2} is an aliphatic group, it may be a chain alkyl group, such as methyl, ethyl, n-propyl, isopropyl, n-butyl, isobutyl, sec-butyl, tert-butyl, n-pentyl, n-hexyl, n-heptyl, n-octyl, 2-ethylhexyl, n-nonyl, n-decyl, n-undecyl, n-tridecyl, n-tetradecyl, n-pentadecyl, n-hexadecyl, n-heptadecyl, n-octadecyl, n-nonadecyl, or n-icosyl; a chain alkenyl group, such as vinyl, 1-propenyl, 2-n-propenyl (allyl), 1-n-butenyl, 2-n-butenyl, or 3-n-butenyl; a cycloalkyl group, such as cyclopropyl, cyclobutyl, cyclopentyl, cyclohexyl, or cycloheptyl; a halogenated chain alkyl group, such as chloromethyl, dichloromethyl, trichloromethyl, bromomethyl, dibromomethyl, tribromomethyl, fluoromethyl, difluoromethyl, trifluoromethyl, 2,2,2-trifluoroethyl, pentafluoroethyl, heptafluoropropyl, perfluorobutyl, perfluoropentyl, perfluorohexyl, perfluoroheptyl, perfluorooctyl, perfluorononyl, or perfluorodecyl; a halogenated cycloalkyl group, such as 2-chlorocyclohexyl, 3-chlorocyclohexyl, 4-chlorocyclohexyl, 2,4-dichlorocyclohexyl, 2-bromocyclohexyl, 3-bromocyclohexyl, or 4-bromocyclohexyl; a hydroxy chain alkyl group, such as hydroxymethyl, 2-hydroxyethyl, 3-hydroxy-n-propyl, or 4-hydroxy-n-butyl; a hydroxycycloalkyl group, such as 2-hydroxycyclohexyl, 3-hydroxycyclohexyl, or 4-hydroxycyclohexyl; a chain alkoxy group, such as methoxy, ethoxy, n-propoxy, isopropoxy, n-butyloxy, isobutyloxy, sec-butyloxy, tert-butyloxy, n-pentyloxy, n-hexyloxy, n-heptyloxy, n-octyloxy, 2-ethylhexyloxy, n-nonyloxy, n-decyloxy, n-undecyloxy, n-tridecyloxy, n-tetradecyloxy, n-pentadecyloxy, n-hexadecyloxy, n-heptadecyloxy, n-octadecyloxy, n-nonadecyloxy, or n-icosyloxy; a chain alkenyloxy group, such as vinyloxy, 1-propenyloxy, 2-n-propenyloxy (allyloxy), 1-n-butenyloxy, 2-n-butenyloxy, or 3-n-butenyloxy; an alkoxyalkyl group, such as methoxymethyl, ethoxymethyl, n-propoxymethyl, 2-methoxyethyl, 2-ethoxyethyl, 2-n-propoxyethyl, 3-methoxy-n-propyl, 3-ethoxy-n-propyl, 3-n-propoxy-n-propyl, 4-methoxy-n-butyl, 4-ethoxy-n-butyl, or 4-n-propoxy-n-butyl; an alkoxyalkoxy group, such as methoxymethoxy, ethoxymethoxy, n-propoxymethoxy, 2-methoxyethoxy, 2-ethoxyethoxy, 2-n-propoxyethoxy, 3-methoxy-n-propoxy, 3-ethoxy-n-propoxy, 3-n-propoxy-n-propoxy, 4-methoxy-n-butyloxy, 4-ethoxy-n-butyloxy, or 4-n-propoxy-n-butyloxy; an aliphatic acyl group, such as formyl, acetyl, propionyl, butanoyl, pentanoyl, hexanoyl, heptanoyl, octanoyl, nonanoyl, or decanoyl; a chain alkyloxycarbonyl group, such as methoxycarbonyl, ethoxycarbonyl, n-propoxycarbonyl, n-butyloxycarbonyl, n-pentyloxycarbonyl, n-hexyloxycarbonyl, n-heptyloxycarbonyl, n-octyloxycarbonyl, n-nonyloxycarbonyl, or n-decyloxycarbonyl; or an aliphatic acyloxy group, such as formyloxy, acetyloxy, propionyloxy, butanoyloxy, pentanoyloxy, hexanoyloxy, heptanoyloxy, octanoyloxy, nonanoyloxy, or decanoyloxy.

In Formula (A1), ma3 is an integer of 1 or more and 10 or less. The value ma3 may be any value of 1 or more and 10 or less, which may be selected as appropriate depending on the structure of X. The value ma3 is preferably 1 or more and 4 or less, more preferably 1 or 2.

In Formula (A1), X is an organic group having 1 or more and 100 or less carbon atoms. The organic group X preferably has 2 or more and 80 or less carbon atoms, more preferably 6 or more and 50 or less carbon atoms. The organic group X may contain a heteroatom, such as O, N, S, P, B, Si, or a halogen atom. In the compound of Formula (A1), the two amino groups are each bonded to a carbon atom in the organic group X.

The organic group X may be aliphatic, aromatic, or a combination of aliphatic and aromatic groups. The organic group X may have a linking group containing a heteroatom, such as oxygen, sulfur, or nitrogen and may be bonded via the linking group. Examples of such a linking group containing a heteroatom (e.g., oxygen, sulfur, nitrogen) in the organic group X include —CONH—, —NH—, —N═N—, —CH═N—, —COO—, —O—, —CO—, —SO—, —SO₂—, —S—, and —S—S—, among which —O—, —CO—, and —S— are preferred.

In a case where the organic group X is an aliphatic group, it may be a saturated or unsaturated aliphatic group. Such an aliphatic group X is preferably an aliphatic hydrocarbon group. Such an aliphatic group X may be a chain group, a cyclic group, or a combination of chain and cyclic aliphatic groups. The chain aliphatic group may be branched.

In a case where the organic group X is an aliphatic group, it is preferably alkylene having 1 or more and 20 or less carbon atoms and lacking (ma1+ma3+2) hydrogen atoms, more preferably alkylene having 1 or more and 16 or less carbon atoms and lacking (ma1+ma3+2) hydrogen atoms, even more preferably alkylene having 1 or more and 12 or less carbon atoms and lacking (ma1+ma3+2) hydrogen atoms.

In a case where the organic group X includes an aromatic group, the moiety composed of the groups X, Ar, R^{a1}, and R^{a2} in Formula (A1) may be a group of any one of Formulae (11) to (15) below.

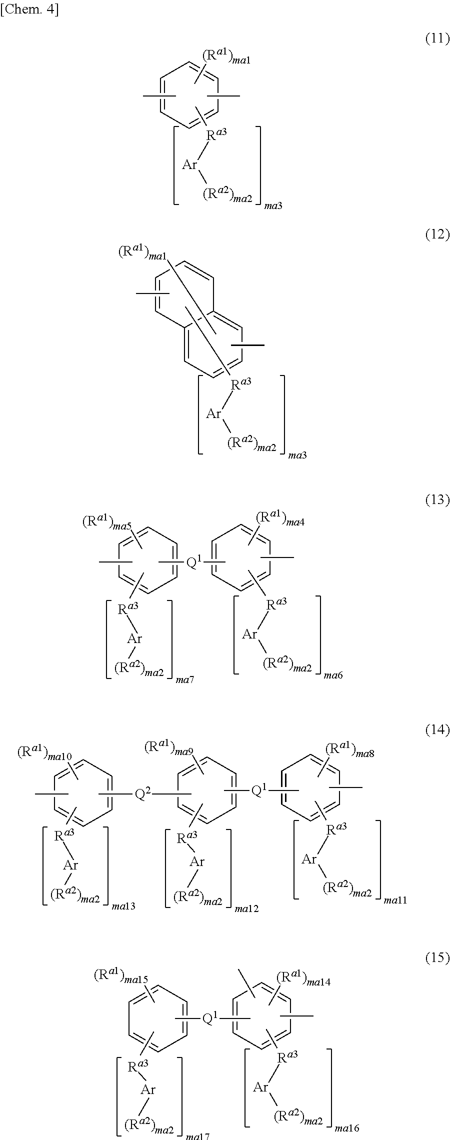

In Formulae (11) to (15), Ar, R^{a1}, R^{a2}, ma1, ma2, and ma3 are the same as those in Formula (A1). In Formula (13), ma4 and ma5 are each independently an integer of 0 or more and 4 or less,

ma6 and ma7 are each independently an integer of 0 or more and 4 or less, and
the sum of ma6 and ma7 is 1 or more and 8 or less. In Formula (14), ma8, ma9, and ma10 are each independently an integer of 0 or more and 4 or less,
the sum of ma8, ma9, and ma10 is 0 or more and 10 or less,
ma11, ma12, and ma13 are each independently an integer of 0 or more and 4 or less, and
the sum of ma11, ma12, and ma13 is 1 or more and 10 or less.
In Formula (15), ma14 is an integer of 0 or more and 3 or less,
ma15 is an integer of 0 or more and 5 or less,
the sum of ma14 and ma15 is 0 or more and 8 or less,
ma16 is an integer of 0 or more and 3 or less,
ma17 is an integer of 0 or more and 5 or less, and
the sum of ma16 and ma17 is 1 or more and 8 or less.

In Formula (11), ma1 is preferably 0, ma2 is preferably 0, and ma3 is preferably 1 or 2. In Formula (12), ma1 is preferably 0, ma2 is preferably 0, and ma3 is preferably 1 or 2. In Formula (13), ma2 is preferably 0, ma4 and ma5 are each preferably 0, ma6 and ma7 are each preferably 0, 1, or 2, and the sum of ma6 and ma7 is preferably 1 or more and 4 or less. In Formula (14), ma2 is preferably 0, ma8, ma9, and ma10 are each preferably 0, ma11, ma12, and ma13 are each preferably 0, 1, or 2, and the sum of ma11, ma12, and ma13 is preferably 1 or more and 6 or less. In Formula (15), ma2 is preferably 0, ma14 and ma15 are each preferably 0, ma16 and ma17 are each preferably 0, 1, or 2, and the sum of ma16 and ma17 is preferably 1 or more and 4 or less.

In Formulae (11) to (15), R^{a3} is a single bond or a divalent linking group. Provided that the divalent linking group is not an aromatic group-containing group. The divalent linking group may be an aliphatic hydrocarbon group having 1 or more and 20 or less carbon atoms, —CONH—, —NH—, —N═N—, —CH═N—, —COO—, —O—, —CO, —SO—, —SO₂—, —S—, —S—S—, or any combination of two or more selected from the above. The linking group preferably has 1 or more and 20 or less carbon atoms, more preferably 1 or more and 12 or less carbon atoms, even more preferably 1 or more and 6 or less carbon atoms. In a case where the linking group is an aliphatic hydrocarbon group, it may have one or more unsaturated bonds, a branched structure, or a ring structure. In a case where the linking group is an aliphatic hydrocarbon group, it may be specifically methylene, ethane-1,2-diyl (ethylene), propane-1,3-diyl, propane-1,2-diyl, propane-1,1-diyl, propane-2,2-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, heptadecane-1,17-diyl, octadecane-1,18-diyl, nonadecane-1,19-diyl, icosane-1,20-diyl, ethene-1,2-diyl (vinylene), propene-1,3-diyl, ethyne-1,2-diyl, or propyne-1,3-diyl.

Preferred examples of the linking group include alkylene having 1 or more and 6 or less carbon atoms, alkenylene having 2 or more and 6 or less carbon atoms, alkynylene having 2 or more and 6 or less carbon atoms, alkyleneoxy having 1 or more and 6 or less carbon atoms, alkenyleneoxy having 2 or more and 6 or less carbon atoms, alkynyleneoxy having 2 or more and 6 or less carbon atoms, alkylenethio having 1 or more and 6 or less carbon atoms, alkenylenethio having 2 or more and 6 or less carbon atoms, alkynylenethio having 2 or more and 6 or less carbon atoms, alkyleneamino having 1 or more and 6 or less carbon atoms, alkenyleneamino having 2 or more and 6 or less carbon atoms, alkynyleneamino having 2 or more and 6 or less carbon atoms, —CONH—, —NH—, —COO—, —O—, —CO—, —SO—, —SO₂—, —S—, —OCONH—, and —OCOO—.

For the formation of a resin film with low dielectric loss tangent and good mechanical properties from the block copolymer, the diamine compound (A-1) of Formula (A1) is preferably a compound of Formula (A1-1) below.

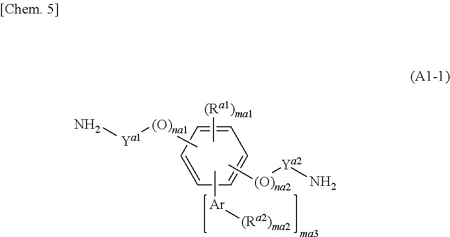

In formula (A1-1), R^{a1}, R^{a2}, Ar, ma1, ma2, and ma3 are the same as those in Formula (A1),

Y^{a1} is an organic group having 1 or more and 20 or less carbon atoms or a single bond,
Y^{a2} is an organic group having 1 or more and 20 or less carbon atoms,
na1 is 0 or 1, and
na2 is 0 or 1,
provided that when na1 is 1, Y^{a1} is not a single bond.

In Formula (A1-1), the organic group Y^{a1} may contain a heteroatom, such as O, N, S, P, B, Si, or a halogen atom. The organic group Y^{a1} is preferably a hydrocarbon group. The hydrocarbon group Y^{a1} may be aliphatic, aromatic, or a combination of aliphatic and aromatic hydrocarbon groups. The hydrocarbon group Y^{a1} is preferably an aromatic hydrocarbon group, more preferably phenylene or naphthalenediyl. Preferred examples of the aromatic hydrocarbon group Y^{a1} include p-phenylene, m-phenylene, o-phenylene, naphthalene-1,4-diyl, naphthalene-1,2-diyl, naphthalene-1,3-diyl, naphthalene-1,5-diyl, naphthalene-1,6-diyl, naphthalene-1,7-diyl, naphthalene-1,8-diyl, naphthalene-2,6-diyl, naphthalene-2,7-diyl, and naphthalene-2,3-diyl. In particular, the aromatic hydrocarbon group Y^{a1} is preferably p-phenylene or m-phenylene, more preferably p-phenylene.

In Formula (A1-1), na2 is preferably 1, na1 and na2 are each more preferably 1, and Ya¹ is more preferably an organic group. In such a case, the structural unit of Formula (A1-1) can be easily well packed to form a block copolymer with good mechanical, thermal, and electrical properties due to a high degree of steric freedom of the ether bond.

In Formula (A1-1), ma1 is preferably 0, ma2 is preferably 0, and ma3 is preferably 1 or 2.

Examples of the diamine compound (A-1) of Formula (A1) include the following compounds.

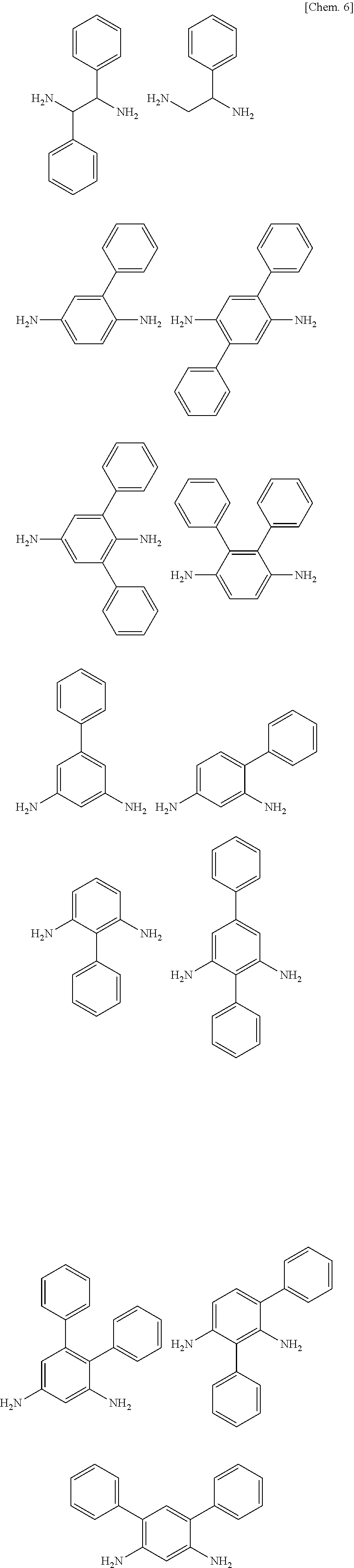

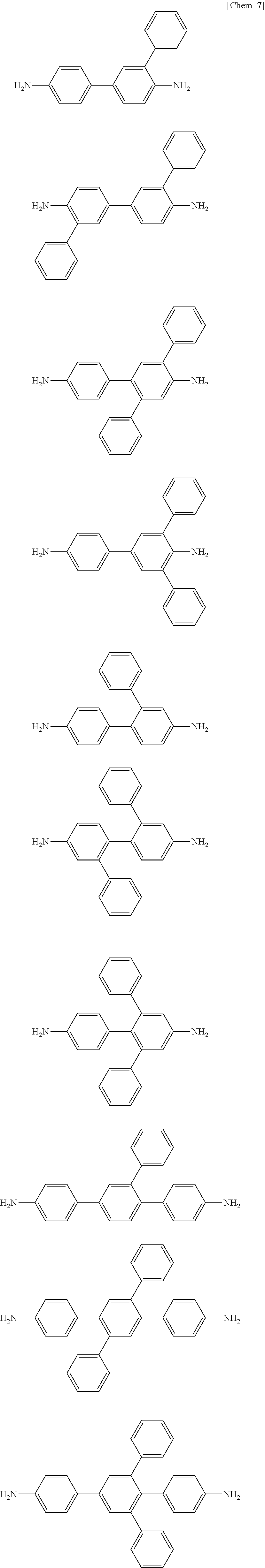

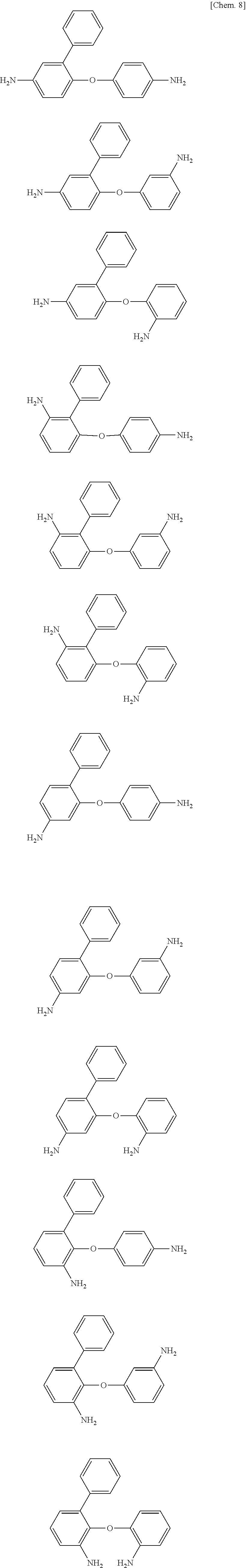

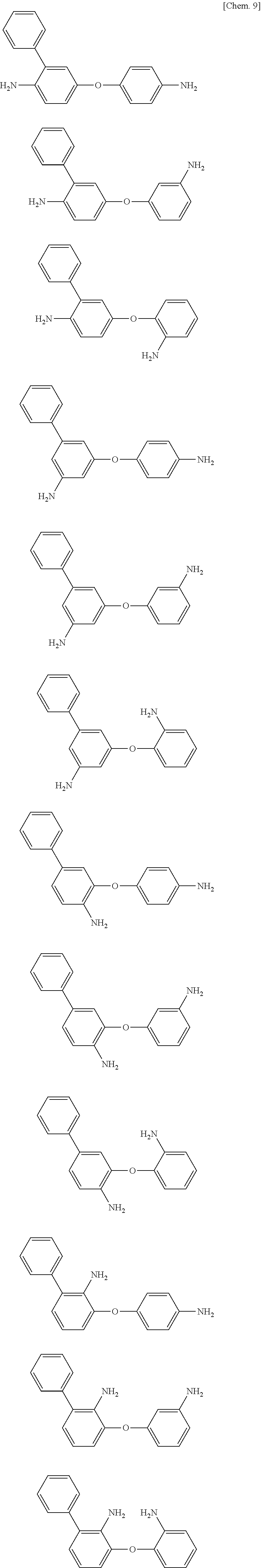

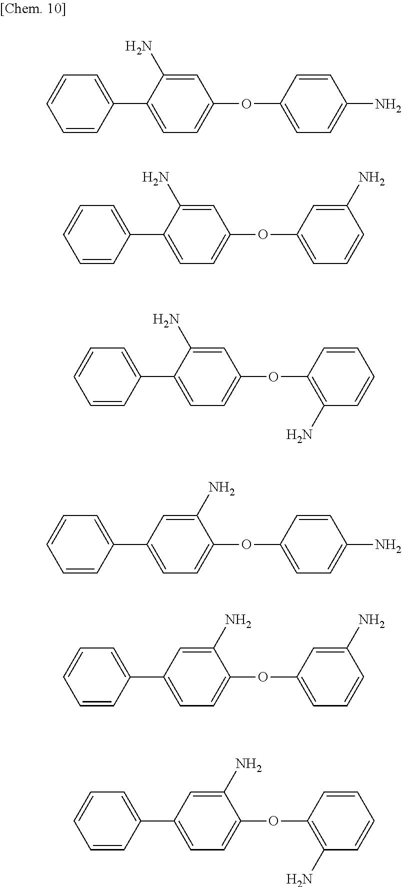

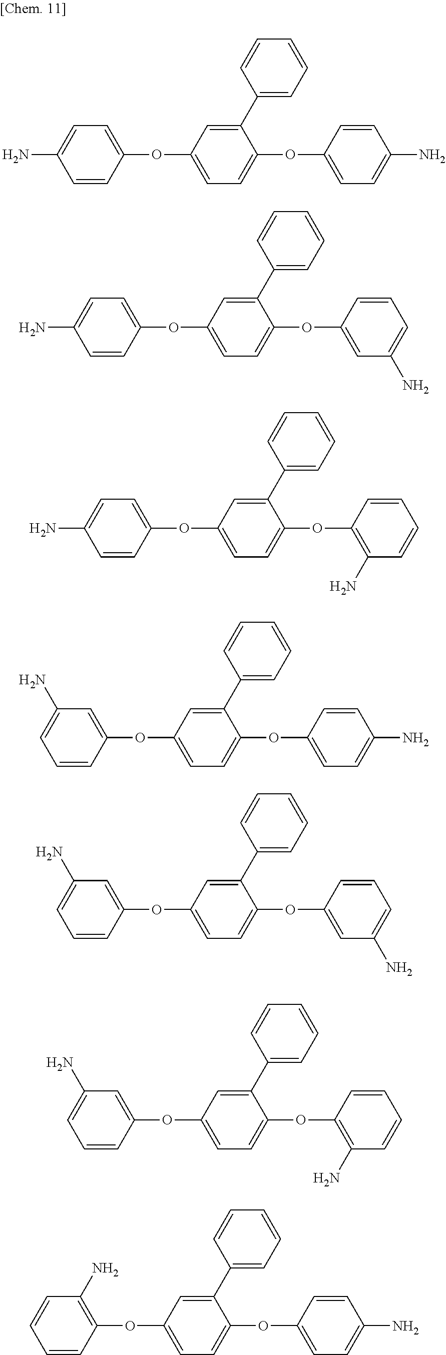

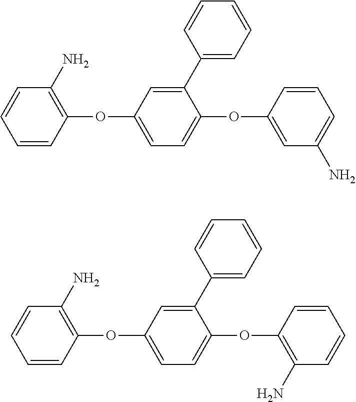 [SMILES: Nc1cccc(Oc2ccc(Oc3ccccc3N)cc2-c2ccccc2)c1 ; Nc1ccccc1Oc1ccc(Oc2ccccc2N)c(-c2ccccc2)c1]

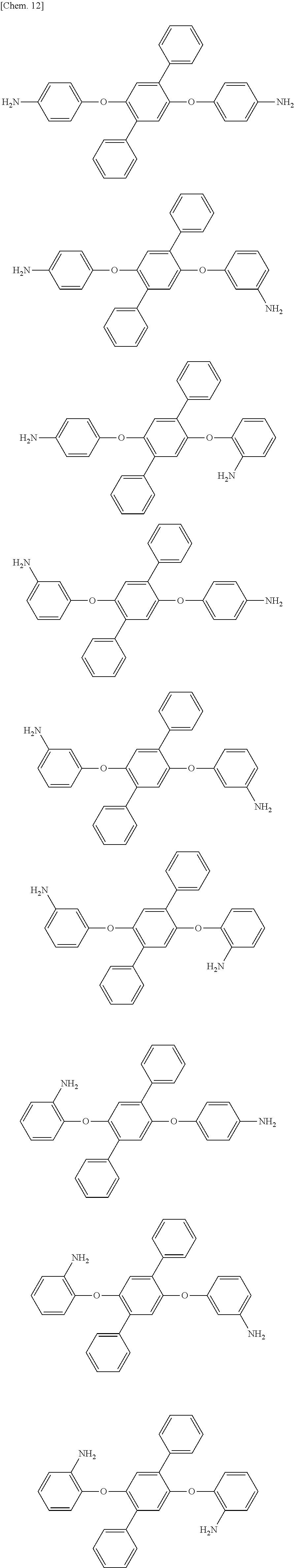

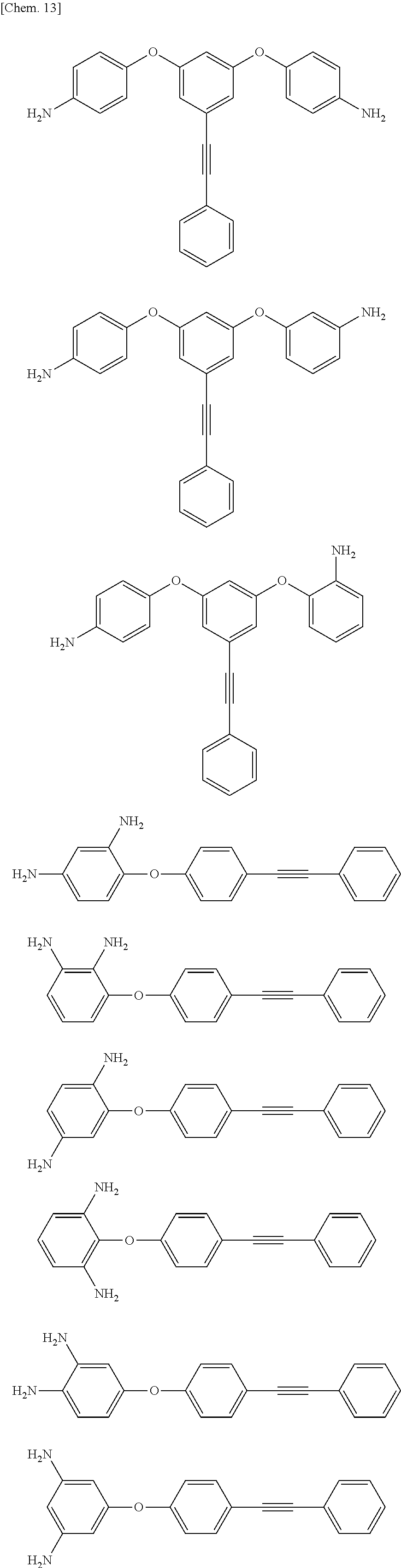

### (Diamine Compound (A-2))

The diamine compound (A-2) is one having a partial structure of Formula (A2) below and not corresponding to the diamine compound (A-1).

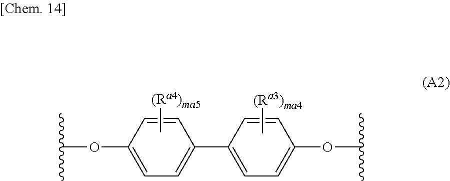

In Formula (A2), R^{a3} and R^{a4} are each independently an alkyl group having 1 or more and 4 or less carbon atoms, an alkoxy group having 1 or more and 4 or less carbon atoms, or a halogen atom, and

ma4 and ma5 are each independently an integer of 0 or more and 4 or less.

Examples of the alkyl group having 1 or more and 4 or less carbon atoms for R^{a3} or R^{a4} in Formula (A2) include methyl, ethyl, n-propyl, isopropyl, n-butyl, isobutyl, sec-butyl, and tert-butyl. In particular, the alkyl group is preferably methyl or ethyl, more preferably methyl. Examples of the alkoxy group having 1 or more and 4 or less carbon atoms for R^{a3} or R^{a4} in Formula (A2) include methoxy, ethoxy, n-propyloxy, isopropyloxy, n-butyloxy, isobutyloxy, sec-butyloxy, and tert-butyloxy. In particular, the alkoxy group is preferably methoxy or ethoxy, more preferably methoxy. Examples of the halogen atom for R^{a3} or R^{a4} in Formula (A2) include fluorine, chlorine, bromine, and iodine. In particular, the halogen atom is preferably chlorine or bromine.

In Formula (A2), ma4 and ma5 are each independently an integer of 0 or more and 4 or less. For easy availability of the diamine compound (A-2), ma4 and ma5 are each preferably an integer of 0 or more and 2 or less, more preferably 0.

The diamine compound (A-2) is preferably a compound of Formula (A2-1) below.

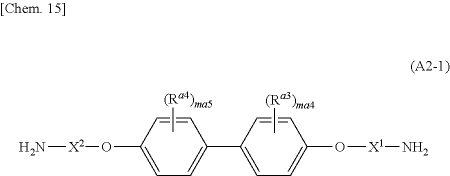

In Formula (A2-1), X¹ and X² are each independently an aromatic hydrocarbon group optionally substituted with one or more selected from the group consisting of an alkyl group having 1 or more and 4 or less carbon atoms, an alkoxy group having 1 or more and 4 or less carbon atoms, and a halogen atom, and

R^{a3}, R^{a4}, ma4, and ma5 are the same as those in Formula (A2).

In Formula (A2-1), X¹ and X² are each independently a divalent aromatic hydrocarbon group optionally substituted with one or more selected from the group consisting of an alkyl group having 1 or more and 4 or less carbon atoms, an alkoxy group having 1 or more and 4 or less carbon atoms, and a halogen atom. Examples of the alkyl substituent having 1 or more and 4 or less carbon atoms include methyl, ethyl, n-propyl, isopropyl, n-butyl, isobutyl, sec-butyl, and tert-butyl. In particular, the alkyl substituent is preferably methyl or ethyl, more preferably methyl. Examples of the alkoxy substituent having 1 or more and 4 or less carbon atoms include methoxy, ethoxy, n-propyloxy, isopropyloxy, n-butyloxy, isobutyloxy, sec-butyloxy, and tert-butyloxy. In particular, the alkoxy substituent is preferably methoxy or ethoxy, more preferably methoxy. Examples of the halogen substituent include fluorine, chlorine, bromine, and iodine. In particular, the halogen substituent is preferably chlorine or bromine.

For example, the number of carbon atoms in the aromatic hydrocarbon group X¹ or X² is preferably, but not limited to, 6 or more and 50 or less, more preferably 6 or more and 20 or less. In this regard, the number of carbon atoms in the substituent(s) is not counted in the number of carbon atoms in the aromatic hydrocarbon group. The aromatic hydrocarbon group X¹ or X² is preferably phenylene, such as o-phenylene, m-phenylene, or p-phenylene, naphthalenediyl, such as naphthalene-1,4-diyl, naphthalene-1,3-diyl, naphthalene-2,6-diyl, or naphthalene-2,7-diyl, or biphenyldiyl, such as biphenyl-4,4′-diyl, biphenyl-3,4′-diyl, or biphenyl-3,3′-diyl.

X¹ or X² is preferably p-phenylene, m-phenylene, naphthalene-1,4-diyl, or biphenyl-4,4′-diyl, more oreferably p-phenylene or biphenyl-4,4′-diyl, even more preferably p-phenylene.

Examples of the diamine compound (A-2) of Formula (A2-1) described above include the following compounds.

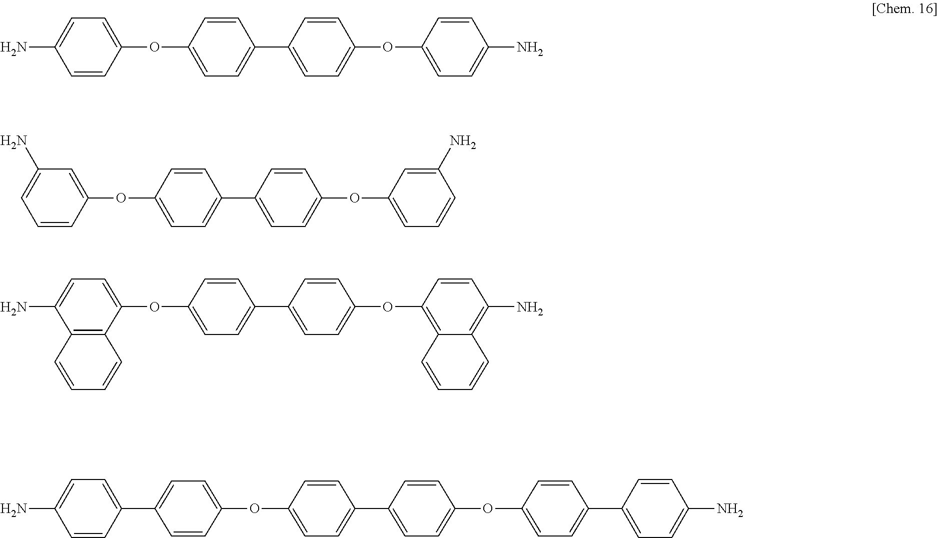 [SMILES: Nc1ccc(Oc2ccc(-c3ccc(Oc4ccc(N)cc4)cc3)cc2)cc1 ; Nc1cccc(Oc2ccc(-c3ccc(Oc4cccc(N)c4)cc3)cc2)c1 ; Nc1ccc(Oc2ccc(-c3ccc(Oc4ccc(N)c5ccccc45)cc3)cc2)c2ccccc12 ; Nc1ccc(-c2ccc(Oc3ccc(-c4ccc(Oc5ccc(-c6ccc(N)cc6)cc5)cc4)cc3)cc2)cc1]

### (Diamine Compound (A-3))

The diamine compound (A-3) is one having a partial structure of Formula (A3) below and not corresponding to the diamine compound (A-1) or the diamine compound (A-2).

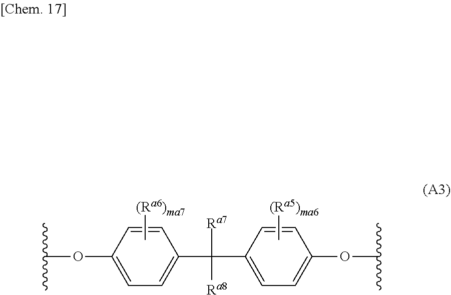

In Formula (A3), R^{a5} and R^{a6} are each independently an alkyl group having 1 or more and 4 or less carbon atoms, an alkoxy group having 1 or more and 4 or less carbon atoms, or a halogen atom,

ma6 and ma7 are each independently an integer of 0 or more and 4 or less,
R^{a7} and R^{a8} are each independently a hydrogen atom, an alkyl group having 1 or more and 4 or less carbon atoms, a halogenated alkyl group having 1 or more and 4 or less carbon atoms, or a phenyl group, and
R^{a7} and R^{a8} may be bonded to each other to form a ring.

Examples of the alkyl group having 1 or more and 4 or less carbon atoms for R^{a5} or R^{a6} in Formula (A3) include methyl, ethyl, n-propyl, isopropyl, n-butyl, isobutyl, sec-butyl, and tert-butyl. In particular, the alkyl group is preferably methyl or ethyl, more preferably methyl. Examples of the alkoxy group having 1 or more and 4 or less carbon atoms for R^{a5} or R^{a6} in Formula (A3) include methoxy, ethoxy, n-propyloxy, isopropyloxy, n-butyloxy, isobutyloxy, sec-butyloxy, and tert-butyloxy. In particular, the alkoxy group is preferably methoxy or ethoxy, more preferably methoxy. Examples of the halogen atom for R^{a5} or R^{a6} in Formula (A3) include fluorine, chlorine, bromine, and iodine. In particular, the halogen atom is preferably chlorine or bromine.

In Formula (A3), ma6 and ma7 are each independently an integer of 0 or more and 4 or less. For easy availability of the diamine compound (A-3), ma6 and ma7 are each preferably an integer of 0 or more and 2 or less, more preferably 0.

Examples of the alkyl group having 1 or more and 4 or less carbon atoms for R^{a7} or R^{a8} in Formula (A3) include methyl, ethyl, n-propyl, isopropyl, n-butyl, isobutyl, sec-butyl, and tert-butyl. Examples of the halogenated alkyl group having 1 or more and 4 or less carbon atoms for R^{a7} or R^{a8} in Formula (A3) include chloromethyl, dichloromethyl, trichloromethyl, bromomethyl, dibromomethyl, tribromomethyl, fluoromethyl, difluoromethyl, trifluoromethyl, 1,1-difluoroethyl, and 1,1,2,2,2-pentafluoroethyl. For high solubility of the block copolymer in organic solvents and for easy availability of the diamine compound (A-3), R^{a7} and R^{a8} in Formula (A3) are each preferably hydrogen, methyl, ethyl, trifluoromethyl, or phenyl. R^{a7} and R^{a8} are also preferably bonded to each other to form a cycloalkylidene group having 5 or more and 8 or less carbon atoms, such as cyclopentylidene, cyclohexylidene, cycloheptylidene, or cyclooctylidene.

Preferred examples of the partial structure of Formula (A3) include the structures below.

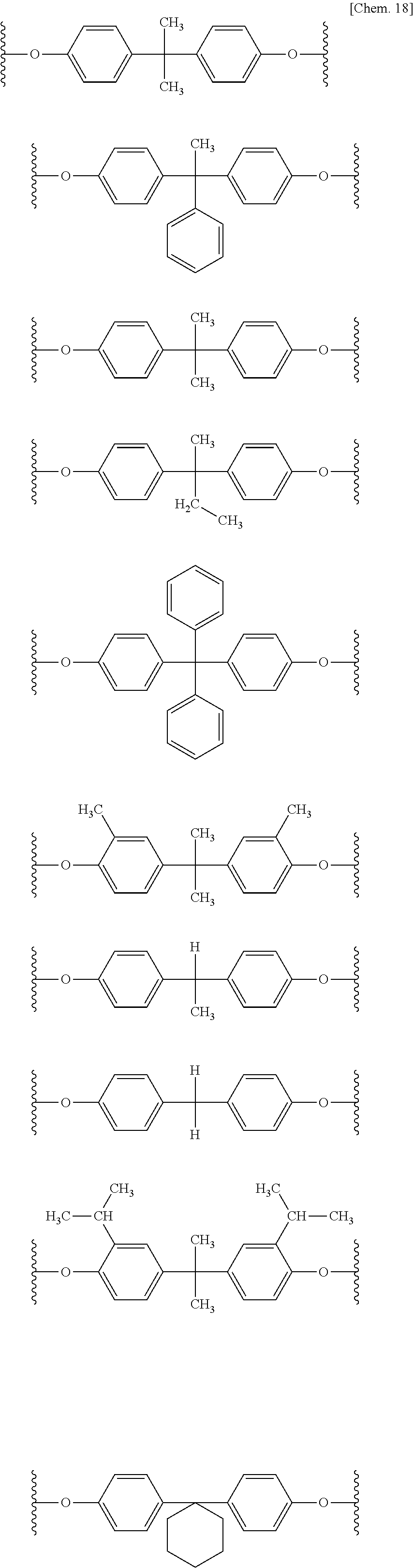

The diamine compound (A-3) is preferably a compound of Formula (A3-1) below.

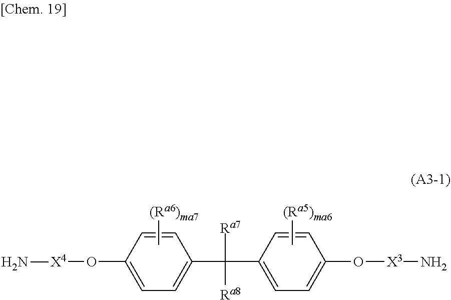

In Formula (A3-1), X³ and X⁴ are each independently an aromatic hydrocarbon group optionally substituted with one or more selected from the group consisting of an alkyl group having 1 or more and 4 or less carbon atoms, an alkoxy group having 1 or more and 4 or less carbon atoms, and a halogen atom, and

R^{a5}, R^{a6}, R^{a7}, R^{a8}, ma6, and ma7 are the same as those in Formula (A3).

In Formula (A3-1), X³ and X⁴ are each independently a divalent aromatic hydrocarbon group optionally substituted with one or more selected from the group consisting of an alkyl group having 1 or more and 4 or less carbon atoms, an alkoxy group having 1 or more and 4 or less carbon atoms, and a halogen atom. Examples of the alkyl substituent having 1 or more and 4 or less carbon atoms include methyl, ethyl, n-propyl, isopropyl, n-butyl, isobutyl, sec-butyl, and tert-butyl. In particular, the alkyl substituent is preferably methyl or ethyl, more preferably methyl. Examples of the alkoxy substituent having 1 or more and 4 or less carbon atoms include methoxy, ethoxy, n-propyloxy, isopropyloxy, n-butyloxy, isobutyloxy, sec-butyloxy, and tert-butyloxy. In particular, the alkoxy substituent is preferably methoxy or ethoxy, more preferably methoxy. Examples of the halogen substituent include fluorine, chlorine, bromine, and iodine. In particular, the halogen substituent is preferably chlorine or bromine.

For example, the number of carbon atoms in the aromatic hydrocarbon group X³ or X⁴ is preferably, but not limited to, 6 or more and 50 or less, more preferably 6 or more and 20 or less. In this regard, the number of carbon atoms in the substituent(s) is not counted in the number of carbon atoms in the aromatic hydrocarbon group. The aromatic hydrocarbon group X³ or X⁴ is preferably phenylene, such as o-phenylene, m-phenylene, or p-phenylene, naphthalenediyl, such as naphthalene-1,4-diyl, naphthalene-1,3-diyl, naphthalene-2,6-diyl, or naphthalene-2,7-diyl, or biphenyldiyl, such as biphenyl-4,4′-diyl, biphenyl-3,4′-diyl, or biphenyl-3,3′-diyl.

X³ or X⁴ is preferably p-phenylene, m-phenylene, naphthalene-1,4-diyl, or biphenyl-4,4′-diyl, more preferably p-phenylene or biphenyl-4,4′-diyl, even more preferably p-phenylene.

Examples of the diamine compound (A-3) of Formula (A3-1) described above include the following compounds.

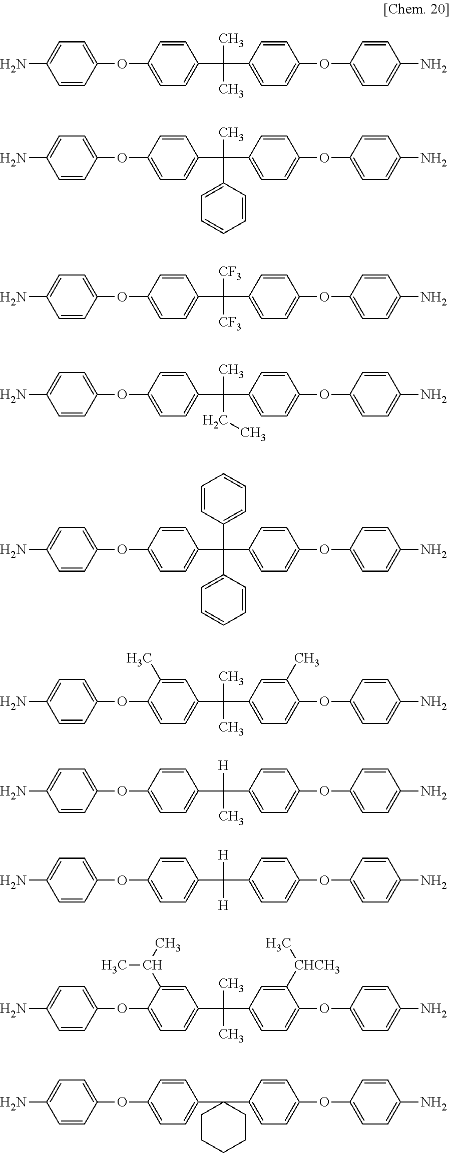

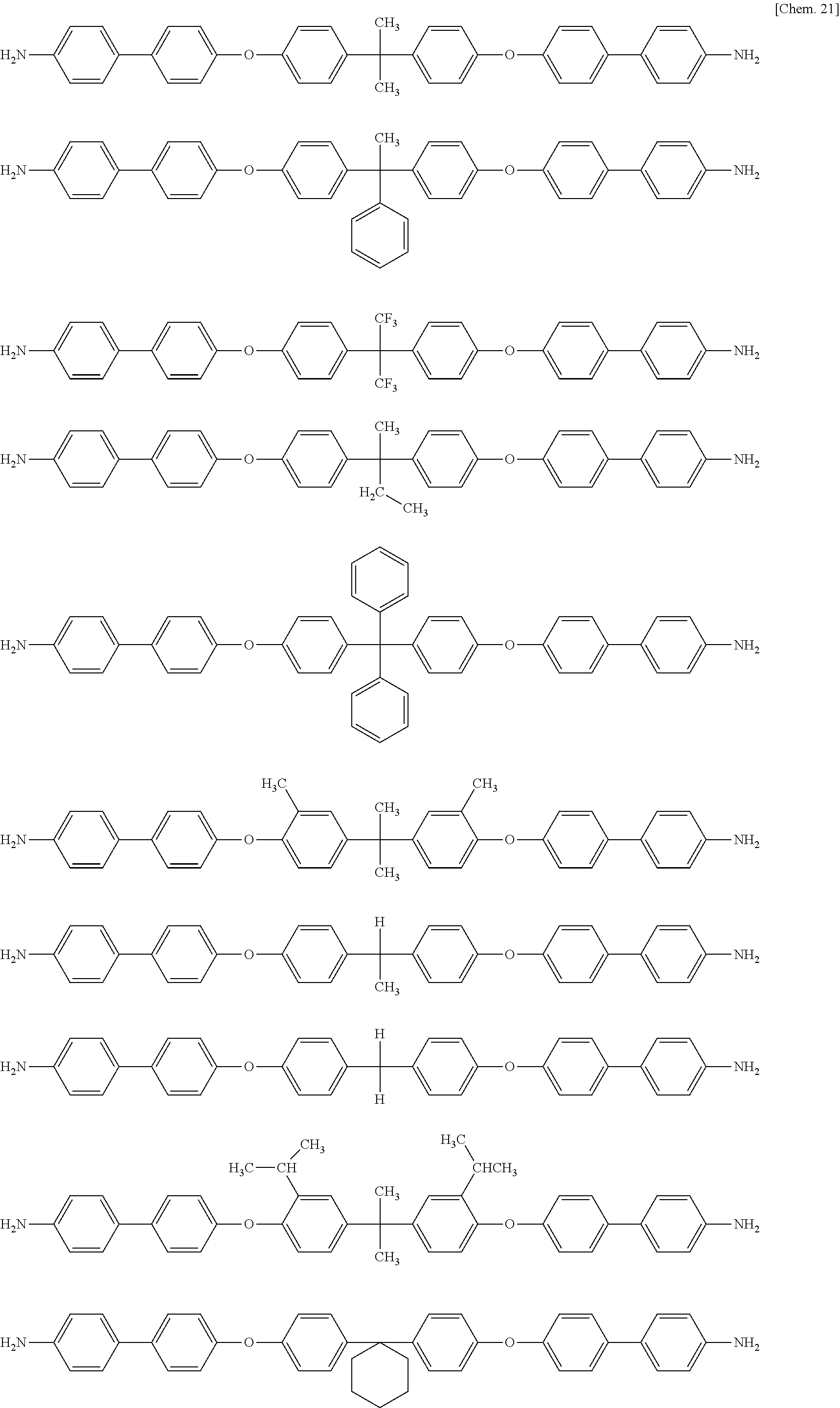

### (Dimer Diamine Compound (A-4))

For ease of forming the block copolymer with low dielectric loss tangent and low permittivity in a high frequency range, the diamine compound is preferably a dimer diamine compound (A-4). The dimer diamine compound (A-4) is a diamine compound derived from a dimer acid by replacing its two terminal carboxy groups with aminomethyl or amino groups. The dimer acid is a known dibasic acid obtained by intermolecular polymerization of unsaturated fatty acid molecules. The dimer acid is produced using almost standardized industrial processes. Typically, the dimer acid is obtained by dimerization of an unsaturated fatty acid having 11 or more and 22 or less carbon atoms in the presence of a clay catalyst or any other catalyst. When industrially produced, a dimer acid product is composed mainly of a dibasic acid having 36 carbon atoms produced by dimerization of an unsaturated fatty acid having 18 carbon atoms, such as oleic acid, linoleic acid, or linolenic acid. When industrially produced, a dimer acid product may contain any amount of a monomer acid having 18 carbon atoms, a trimer acid having 54 carbon atoms, and other polymerized fatty acids having 20 or more and 54 or less carbon atoms, depending on the degree of purification. The dimer diamine compound (A-4) is preferably a diamine compound of Formula (31) below.

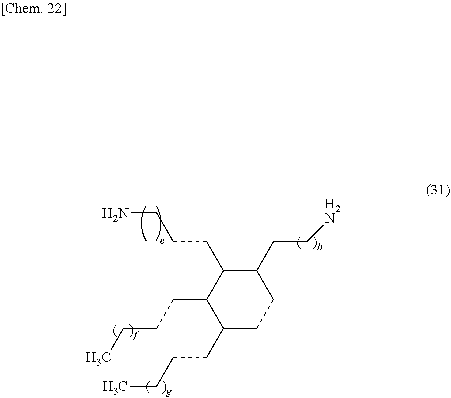

In Formula (31), e, f, g, and h are each an integer of 0 or more,

e+f is an integer of 6 or more and 17 or less,
g+h is an integer of 8 or more and 19 or less, and the broken line indicates a carbon-carbon single bond or a carbon-carbon double bond.

To allow the formation of a cured product with a high elongation, the diamine compound of Formula (31) is preferably a compound of Formula (32) below.

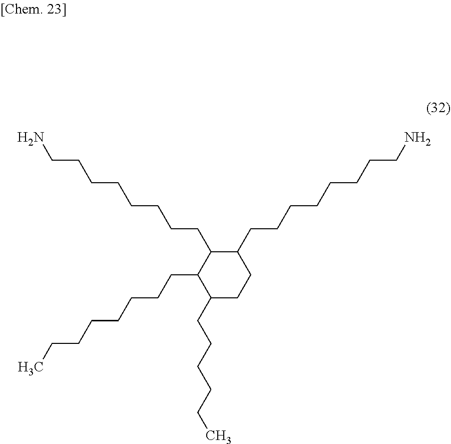 [SMILES: CCCCCCCCC1C(CCCCCC)CCC(CCCCCCCCN)C1CCCCCCCCN]

The diamine compound of Formula (31) may be a commercially available product, examples of which include Versamine 551 (manufactured by BASF) and Priamine 1074 (manufactured by Croda Japan), which include a compound of Formula (33) below, and Versamine 552 (manufactured by BASF), Priamine 1073 (manufactured by Croda Japan), and Priamine 1075 (manufactured by Croda Japan), which include the compound of Formula (32) above. Such a commercially available dimer diamine compound (A-4) is usually a mixture including two or more amine compounds.

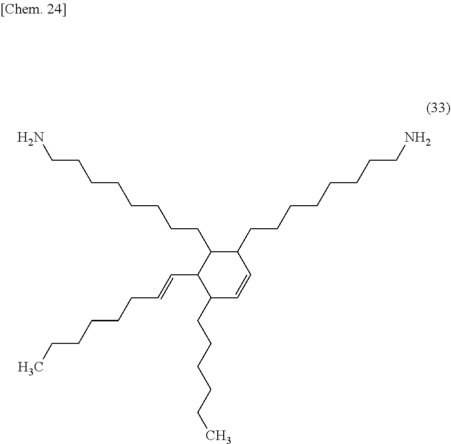 [SMILES: CCCCCC/C=C/C1C(CCCCCC)C=CC(CCCCCCCCN)C1CCCCCCCCN]

The diamine compound of Formula (31) may be allowed to react with an acid halide derived from trimellitic anhydride to form a tetracarboxylic dianhydride of Formula (34) below. The tetracarboxylic dianhydride of Formula (34) below is preferably used as a raw material for the production of the polyamide macromonomer, the polyimide macromonomer, or the block copolymer. In Formula (34), i, j, k, and l are each an integer of 0 or more,

i+j is an integer of 6 or more and 17 or less, k+l is 8 or more and 19 or less, and
the broken line indicates a carbon-carbon single bond or a carbon-carbon double bond.

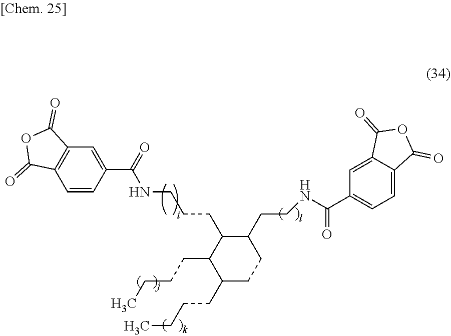

The ratio of the number of moles of at least one compound selected from the group consisting of the diamine compounds (A-1), (A-2), and (A-3) and the dimer diamine compound (A-4) to the total number of moles of the diamine compounds is preferably 10 mol % or more and 100 mol % or less, more preferably 15 mol % or more and 100 mol % or less, even more preferably 20 mol % or more and 100 mol % or less.

[Dicarboxylic Acid Resulting from Reaction of Tetracarboxylic Dianhydride with Alcohol]

The dicarboxylic acid used to produce the polyamide macromonomer is a product resulting from reaction of a tetracarboxylic dianhydride with an alcohol. As used hereinafter, unless otherwise specified, the term “dicarboxylic acid” means a product resulting from reaction of a tetracarboxylic dianhydride with an alcohol, which is for use in the production of the polyamide macromonomer. Hereinafter, the tetracarboxylic dianhydride and the alcohol will be described.

### (Tetracarboxylic Dianhydride)

The tetracarboxylic dianhydride may be any type that does not compromise the desired effect. The tetracarboxylic dianhydride is typically one used for the production of polyamic acid and polyimide resin in the art. The tetracarboxylic dianhydride may be a compound of Formula (A3) below.

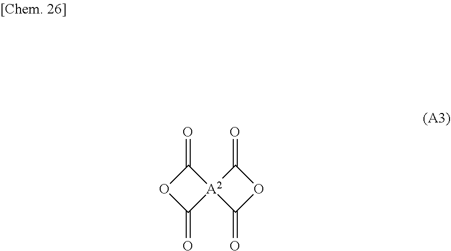

In Formula (A3), A² is a tetravalent organic group having 6 or more and 50 or less carbon atoms.

In Formula (A3), A² is a tetravalent organic group having 6 or more and 50 or less carbon atoms, which may be substituted with one or more substituents in addition to the two —CO—O—CO— groups in Formula (A3). Preferred examples of the substituent include fluorine, alkyl having 1 or more and 6 or less carbon atoms, alkoxy having 1 or more and 6 or less carbon atoms, fluorinated alkyl having 1 or more and 6 or less carbon atoms, and fluorinated alkoxy having 1 or more and 6 or less carbon atoms. The compound of Formula (A3) may also contain a carboxy group or a carboxylic acid ester group in addition to the acid anhydride groups. In a case where the substituent is fluorinated alkyl or fluorinated alkoxy, it is preferably perfluoroalkyl or perfluoroalkoxy. Regarding the substituent, the same applies to one or more substituents with which the aromatic group described later may be substituted on the aromatic ring.

The number of carbon atoms in A² is preferably 8 or more, more preferably 12 or more. The number of carbon atoms in A² is preferably 40 or less, more preferably 30 or less. A² may be an aliphatic group, an aromatic group, or a combination of aliphatic and aromatic groups. In addition to carbon and hydrogen atoms, the group A² may contain halogen, oxygen, nitrogen, and sulfur atoms. In a case where A² contains an oxygen, nitrogen, or sulfur atom, A² may have a group selected from a nitrogen-containing heterocyclic group, —CONH—, —NH—, —N═N—, —CH═N—, —COO—, —O—, —CO—, —SO—, —SO₂—, —S—, or —S—S— as an oxygen-, nitrogen-, or sulfur-containing group, and more preferably has a group selected from —O—, —CO—, or —S—.

The tetracarboxylic dianhydride of Formula (A3) may be an aliphatic tetracarboxylic dianhydride having an aliphatic group and two dicarboxylic anhydride groups bonded to the aliphatic group or may be an aromatic tetracarboxylic dianhydride having an aromatic group and at least one dicarboxylic anhydride group bonded to the aromatic group. The aromatic tetracarboxylic dianhydride preferably has two dicarboxylic anhydride groups bonded to the aromatic group.

The aliphatic tetracarboxylic dianhydride may contain an alicyclic structure. The alicyclic structure may be polycyclic. Examples of the aliphatic tetracarboxylic dianhydride having no alicyclic structure include 1,2,3,4-tetracarboxylic dianhydride (e.g., RIKACID BT-100 manufactured by New Japan Chemical Co., Ltd.). Examples of the aliphatic tetracarboxylic dianhydride having an alicyclic structure include cyclobutanetetracarboxylic dianhydride, cyclopentane-1,2,3,4-tetracarboxylic dianhydride, cyclohexane-1,2,4,5-tetracarboxylic dianhydride, norbornane-2-spiro-a-cyclopentanone-α′-spiro-2″-norbornane-5,5″,6,6″-tetracarboxylic dianhydride (e.g., ENEHYDE® CpODA manufactured by ENEOS Corporation), 2,2-bis(2,3-dicarboxyphenoxy)hexafluoropropane dianhydride, [5,5′-(1,4-phenylene)bisnorbornane]-2,2′,3,3′-tetracarboxylic dianhydride (e.g., ENEHYDE® BzDA manufactured by ENEOS Corporation), and 1,3,3a,4,5,9b-hexahydro-5(tetrahydro-2,5-dioxo-3-furanyl)naphtho[1,2-C]furan-1,3-dione (e.g., RIKACID TDA-100 manufactured by New Japan Chemical Co., Ltd.).

Examples of the aromatic tetracarboxylic dianhydride of Formula (A3) having two dicarboxylic anhydride groups bonded to the aromatic group include pyromellitic dianhydride, 1,4-bis(3,4-dicarboxyphenoxy)benzene dianhydride, 4,4′-oxydiphthalic dianhydride, 3,3′,4,4′-biphenyltetracarboxylic dianhydride, 2,3,3′,4′-biphenyltetracarboxylic dianhydride, 3,3′,4,4′-benzophenonetetracarboxylic dianhydride, 2,2′,3,3′-benzophenonetetracarboxylic dianhydride, 3,3′,4,4′-diphenylsulfonetetracarboxylic dianhydride, 3,3′,4,4′-diphenylsulfidetetracarboxylic dianhydride, trimellitic (3,4-dicarboxyphenyl) dianhydride, 1,2,5,6-naphthalenetetracarboxylic dianhydride, 2,3,6,7-naphthalenetetracarboxylic dianhydride, 2,3,5,6-pyridinetetracarboxylic dianhydride, 3,4,9,10-perylenetetracarboxylic dianhydride, bis(2,3-dicarboxyphenoxy)methane dianhydride, 1,1-bis(2,3-dicarboxyphenoxy)ethane dianhydride, 2,2-bis[4-(3,4-dicarboxyphenyloxy)phenyl]propane dianhydride, 4,4′-bis(3,4-dicarboxyphenylcarbonyloxy)biphenyl dianhydride, 2,6-bis(3,4-dicarboxyphenylcarbonyloxy)naphthalene dianhydride, 1,2-bis(3,4-dicarboxyphenylcarbonyloxy)ethane dianhydride (e.g., RIKACID TMEG-100 manufactured by New Japan Chemical Co., Ltd.), and 1,10-bis (3,4-dicarboxyphenylcarbonyloxy)decane dianhydride (e.g., 10BTA manufactured by Kurogane Kasei Co., Ltd.). In particular, for ease of forming a cured product with good electrical properties, the aromatic tetracarboxylic dianhydride is preferably 2,2-bis[4-(3,4-dicarboxyphenyloxy)phenyl]propane dianhydride, 4,4′-bis(3,4-dicarboxyphenylcarbonyloxy)biphenyl dianhydride, 4,4′-bis(3,4-dicarboxyphenyloxy)biphenyl dianhydride, 2,6-bis(3,4-dicarboxyphenylcarbonyloxy)naphthalene dianhydride, or α,ω-bis(3,4-dicarboxyphenylcarbonyloxy)alkane dianhydride. The number of carbon atoms in the linear alkylene group of α,ω-bis(3,4-dicarboxyphenylcarbonyloxy)alkane dianhydride is preferably 1 or more and 20 or less, more preferably 2 or more and 12 or less. Preferred examples of α,ω-bis(3,4-dicarboxyphenylcarbonyloxy)alkane dianhydride include 1,2-bis(3,4-dicarboxyphenylcarbonyloxy) ethane dianhydride (e.g., RIKACID TMEG 100 manufactured by New Japan Chemical Co., Ltd.) and 1,10-bis(3,4-dicarboxyphenylcarbonyloxy)decane dianhydride (e.g., 10BTA manufactured by Kurogane Kasei Co., Ltd.).

The aromatic tetracarboxylic dianhydride is also preferably biphenyltetracarboxylic dianhydride, which can form a block copolymer-containing composition that can form a film less likely to warp or which can form a block copolymer-containing photosensitive composition having good photolithographic properties. The biphenyltetracarboxylic dianhydride is preferably 3,3′,4,4′-biphenyltetracarboxylic dianhydride, 2,3,3′,4′-biphenyltetracarboxylic dianhydride, 2,2′,3,3′-biphenyltetracarboxylic dianhydride, or 3,3′,4,4′-biphenyltetracarboxylic dianhydride.

The aromatic tetracarboxylic dianhydride may also be, for example, any one of compounds of Formulae (a3-2) to (a3-4) below.

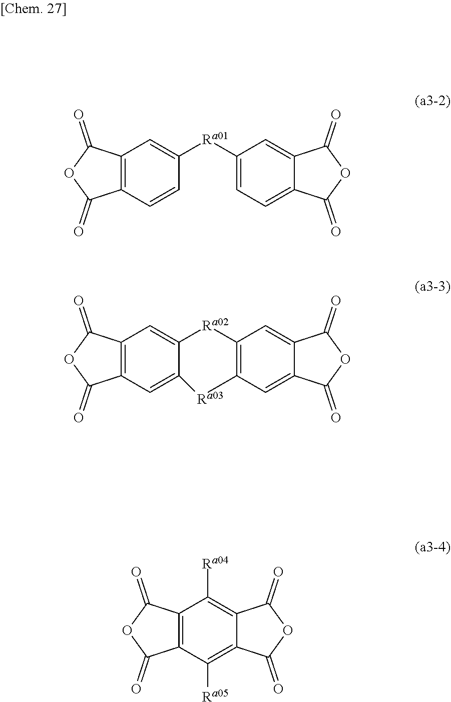

In Formulae (a3-2) and (a3-3), R^{a01}, R^{a02}, and R^{a03} are each any one of an optionally halo-substituted aliphatic group, an oxygen atom, a sulfur atom, or an aromatic group with one or more divalent intervening atoms or each a divalent group including any combination thereof, and

R^{a02} and R^{a03} may be the same or different. In other words, R^{a01}, R^{a02}, and R^{a03} may contain a carbon-carbon single bond, a carbon-oxygen-carbon ether bond, or a halogen atom (fluorine, chlorine, bromine, or iodine). Examples of the compound of Formula (a3-2) include 2,2-bis(3,4-dicarboxyphenoxy)propane dianhydride, bis(3,4-dicarboxyphenoxy)methane dianhydride, 1,1-bis(3,4-dicarboxyphenoxy)ethane dianhydride, 1,3-bis(3,4-dicarboxyphenoxy)benzene dianhydride, 2,2-bis(3,4-dicarboxyphenoxy)hexafluoropropane dianhydride, and 1,4-bis(3,4-dicarboxyphenoxy)benzene dianhydride.

In Formula (a3-4), R^{a04} and R^{a05} are each any one of an optionally halo-substituted aliphatic group, an aromatic group with one or more divalent intervening atoms, or halogen or each a monovalent substituent including any combination thereof, and

R^{a04} and R^{a05} may be the same or different. Examples of the compound of Formula (a3-4) that may be used include difluoropyromellitic dianhydride and dichloropyromellitic dianhydride.

The block copolymer also preferably has a radically polymerizable group-containing group on its molecular chain. For such a structure, the tetravalent organic group A² in Formula (A3) may be a group of any one of Formulae (a3-5) to (a3-7) below.

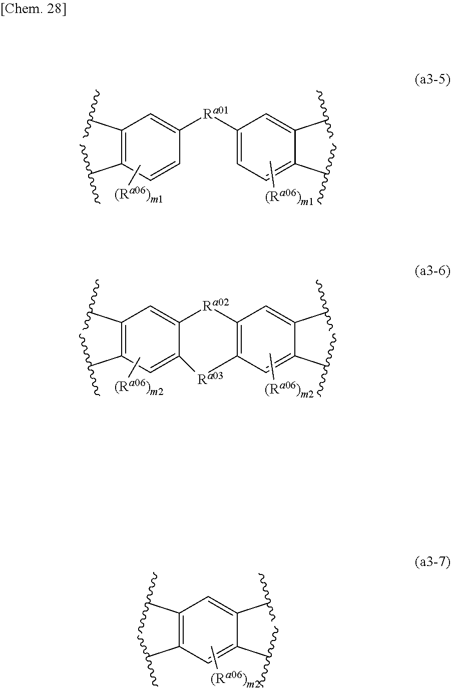

In Formulae (a3-5) to (a3-7), R^{a01}, R^{a02}, and R^{a03} are the same as R^{a01}, R^{a02}, and R^{a03} in Formulae (a3-2), (a3-3), and (a3-4). In Formulae (a3-5), (a3-6), and (a3-7), R^{a06} is a radically polymerizable group-containing group. The radically polymerizable group-containing group will be described later.

### (Alcohol)

As mentioned above, the dicarboxylic acid is a product resulting from reaction of the tetracarboxylic dianhydride with an alcohol.

The alcohol may have any structure that does not compromise the desired effect. The alcohol preferably has a radically polymerizable group so that it can form a block copolymer having photosensitivity or can form a block copolymer-containing, resin film-forming composition having photosensitivity. The radically polymerizable group is typically an ethylenically unsaturated double bond-containing group. The ethylenically unsaturated double bond-containing group is preferably an alkenyl group-containing group, which contains an alkenyl group, such as vinyl or allyl, and more preferably a (meth)acryloyl group-containing group.

Examples of the alcohol capable of reacting with the tetracarboxylic dianhydride to form the dicarboxylic acid compound include alkane monools, such as methanol, ethanol, n-propanol, isopropanol, n-butanol, n-pentanol, and n-hexanol; phenols or naphthols, such as phenol, p-cresol, m-cresol, o-cresol, α-naphthol, and β-naphthol; glycol monoethers, such as ethylene glycol monomethyl ether, ethylene glycol monoethyl ether, propylene glycol monomethyl ether, propylene glycol monoethyl ether, 1,3-propanediol monomethyl ether, 1,3-propanediol monoethyl ether, diethylene glycol monomethyl ether, diethylene glycol monoethyl ether, dipropylene glycol monomethyl ether, and dipropylene glycol monoethyl ether; and alcohols having the radically polymerizable group.

Preferred examples of the radically polymerizable group-containing alcohol include diol mono(meth)acrylates, N-hydroxyalkyl-substituted (meth)acrylamides, hydroxyl group-containing unsaturated ketones, alkenyl alcohols, and monoalkenyl ethers of diols containing an alkenyl group having 3 or more carbon atoms.

Examples of the diol capable of forming diol mono(meth)acrylates include alkane diols (alkylene glycols), such as ethylene glycol, 1,2-propanediol, and 1,3-propanediol; oligo- or poly-alkylene glycols, such as diethylene glycol, dipropylene glycol, triethylene glycol, and tripropylene glycol; and cycloalkanediols, such as 1,4-cyclohexanediol, 1,3-cyclohexanediol, and 1,2-cyclohexanediol. These diols are non-limiting examples of the diol capable of forming diol mono(meth)acrylates. The alkanediol preferably has 2 or more and 10 or less carbon atoms, more preferably 2 or more and 6 or less carbon atoms, even more preferably 2 or more and 4 or less carbon atoms. The oligo- or poly-alkylene glycol preferably has 4 or more and 20 or less carbon atoms, more preferably 4 or more and 10 or less carbon atoms. The cycloalkanediol preferably has 4 or more and 8 or less carbon atoms, more preferably 5 or more and 7 or less carbon atoms. The alkanediol and the oligo- or poly-alkylene glycol may be linear or branched.

The N-hydroxyalkyl group of the N-hydroxyalkyl-substituted (meth)acrylamide preferably has 2 or more and 10 or less carbon atoms, more preferably 2 or more and 6 or less carbon atoms, even more preferably 2 or more and 4 or less carbon atoms. The N-hydroxyalkyl group of the N-hydroxyalkyl-substituted (meth)acrylamide may be linear or branched.

The hydroxyl group-containing unsaturated ketone is preferably a compound having hydroxyalkyl and alkenyl groups bonded to the carbonyl group. The hydroxyalkyl group preferably has 2 or more and 10 or less carbon atoms, more preferably 2 or more and 6 or less carbon atoms, even more preferably 2 or more and 4 or less carbon atoms. The hydroxyalkyl group may be linear or branched. The alkenyl group preferably has 2 or more and 10 or less carbon atoms, more preferably 2 or more and 6 or less carbon atoms, even more preferably 2 or more and 4 or less carbon atoms. The alkenyl group may be linear or branched.

The alkenyl alcohol preferably has 3 or more and 10 or less carbon atoms, more preferably 3 or more and 6 or less carbon atoms, even more preferably 3 or 4 carbon atoms. The alkenyl alcohol may be linear or branched.

The diols capable of forming the monoalkenyl ethers of diols containing an alkenyl group having 3 or more carbon atoms may be the same as those capable of forming the diol mono(meth)acrylates. The alkenyl group preferably has 3 or more and 10 or less carbon atoms, more preferably 3 or more and 6 or less carbon atoms. The alkenyl group may be linear or branched.

Preferred examples of the radically polymerizable group-containing alcohol include diol mono(meth)acrylates, such as 2-hydroxyethyl (meth)acrylate, 3-hydroxypropyl (meth)acrylate, 2-hydroxypropyl (meth)acrylate, 2-hydroxy-3-methoxypropyl (meth)acrylate, 2-hydroxy-3-butoxypropyl (meth)acrylate, 2-hydroxy-3-tert-butyloxypropyl (meth)acrylate, 2-hydroxy-3-phenoxypropyl (meth)acrylate, 2-hydroxy-3-cyclohexyloxypropyl (meth)acrylate, 3-hydroxypropan-2-yl (meth)acrylate, 4-hydroxybutyl (meth)acrylate, 2-hydroxybutyl (meth)acrylate, 5-hydroxypentyl (meth)acrylate, 6-hydroxyhexyl (meth)acrylate, 2-(2-hydroxyethoxy)ethyl (meth)acrylate, and 1-(2-(meth)acryloyloxyethyl) 2-(2-hydroxypropyl) phthalate; N-hydroxyalkyl-substituted (meth)acrylamides, such as N-(2-hydroxyethyl) (meth)acrylamide, and N-(3-hydroxypropyl) (meth)acrylamide; hydroxyl group-containing ketones, such as (hydroxymethyl)vinyl ketone and (2-hydroxymethyl)vinyl ketone; alkenyl alcohols, such as allyl alcohol, 4-buten-1-ol, 5-hexen-1-ol, 3-hexen-1-ol, 6-hepten-1-ol, 5-octen-1-ol, 3-octen-1-ol, 3-nonen-1-ol, 6-nonen-1-ol, 9-decen-1-ol, 4-decen-1-ol, 10-undecen-1-ol, 11-dodecen-1-ol, elaidolinoleyl alcohol, oleyl alcohol, linoleyl alcohol, linolenyl alcohol, and erucyl alcohol; monoalkenyl ethers or diols containing an alkenyl group having 3 or more carbon atoms, such as ethylene glycol monoallyl ether, 2-allyloxypropan-1-ol, 1-allyloxypropan-2-ol, 1,3-propanediol monoallyl ether, 1,4-butanediol monoallyl ether, 1,5-pentanediol monoallyl ether, and 1,6-hexanediol monoallyl ether. As used herein, the term “(meth)acrylate” means both acrylate and methacrylate.

### (Production of Dicarboxylic Acid)

The tetracarboxylic dianhydride and the alcohol described above are allowed to react to form a polymerizable dicarboxylic acid. The alcohol reacts with the carboxylic anhydride groups to produce a carboxy group and an ester group.

The tetracarboxylic dianhydride may be allowed to react with an alcohol represented by R^{a21}—OH to produce a dicarboxylic acid. R^{a21} is a residue of the alcohol lacking a hydroxyl group. Such a dicarboxylic acid includes adjacent carbon atoms; and two pairs of a carboxy group and a —CO—O—R^{a21} group, which are located on the adjacent carbon atoms.

The dicarboxylic acid having two pairs of a carboxy group and a —CO—O—R^{a21} group may have isomers different in the positions of the carboxy group and the —CO—O—R^{a21} group. The dicarboxylic acid may be one of such isomers or a combination of two or more of such isomers. The specification of the present application and the claims encompass embodiments in which the blocks derived from the polyamide macromonomer and the polyimide macromonomer include two or more structural units derived from two or more isomers of the dicarboxylic acid.

As an example, the dicarboxylic acid derived from pyromellitic dianhydride has isomers including a compound of Formula (a4-a1) below and a compound of Formula (a4-a2) below. As another example, the dicarboxylic acid derived from 1,4-bis(3,4-dicarboxyphenoxy)benzene dianhydride has isomers including a compound of Formula (a4-b1) below, a compound of Formula (a4-b2) below, and a compound of Formula (a4-b3) below. In each of the Formulae (a4-a1), (a4-a2), and (a4-b1) to (a4-b3) below, R^{a21}=is as defined above.

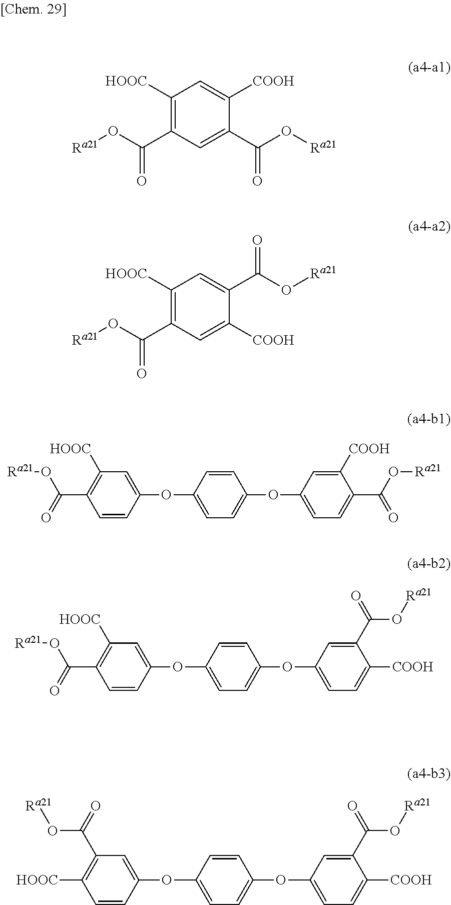

Examples of the dicarboxylic acids derived from the tetracarboxylic dianhydrides of Formulae (a3-2) to (a3-4) above include compounds of Formulae (a4-2a) to (a4-2c) below, compounds of Formulae (a4-3a) to (a4-3c) below, and compounds of Formulae (a4-4a) to (a4-4c) below. In Formulae (a4-2a) to (a4-2c), (a4-3a) to (a4-3c), and (a4-4a) to (a4-4c), R^{a01} to R^{a05} are the same as those in Formulae (a3-2) to (a3-4). In Formulae (a4-2a) to (a4-2c), (a4-3a) to (a4-3c), and (a4-4a) to (a4-4c), R^{a21} is as defined above.

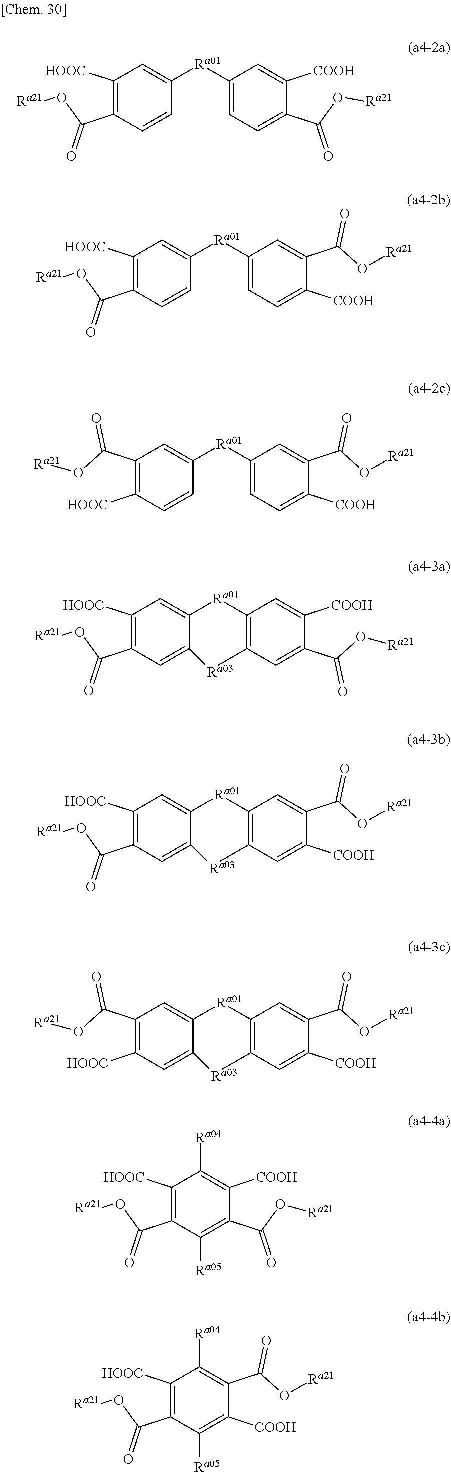

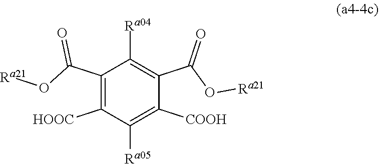

Examples of the dicarboxylic acids derived from the tetracarboxylic dianhydrides of Formulae (a3-5) to (a3-7) above include compounds of Formulae (a4-5a) to (a4-5c) below, compounds of Formulae (a4-6a) to (a4-6c) below, and compounds of Formulae (a4-7a) and (a4-7b) below. In Formulae (a4-5a) to (a4-5c), (a4-6a) to (a4-6c), and (a4-7a) and (a4-7b), R^{a01} to R^{a03}, Rₐ₀₆, m1, and m2 are the same as those in Formulae (a3-5) to (a3-7). In Formulae (a4-5a) to (a4-5c), (a4-6a) to (a4-6c), and (a4-7a) and (a4-7b), R^{a21} is as defined above.

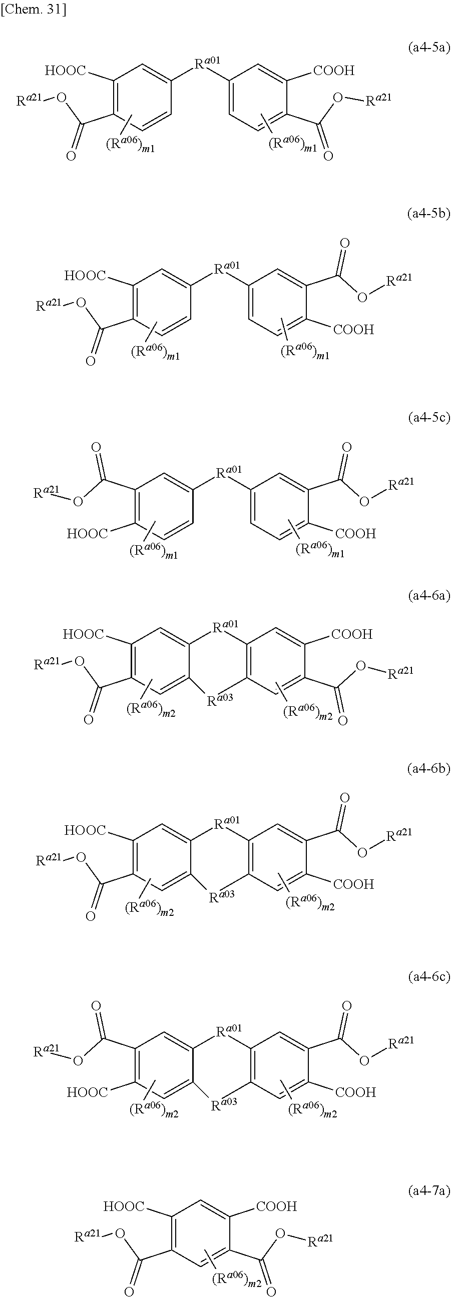

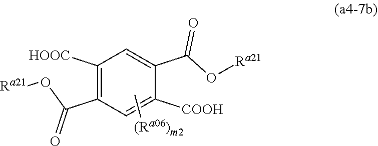

The reaction of the tetracarboxylic dianhydride with the alcohol is usually performed in an organic solvent. The organic solvent used for the reaction of the tetracarboxylic dianhydride with the alcohol may be any type that can dissolve the tetracarboxylic dianhydride and the alcohol and will neither react with the tetracarboxylic dianhydride nor with the alcohol. A single organic solvent may be used, or a mixture of two or more organic solvents may be used.

Examples of the organic solvent used for the reaction of the tetracarboxylic dianhydride with the alcohol include nitrogen-containing polar solvents, such as N-methyl-2-pyrrolidone, N-ethyl-2-pyrrolidone, 1,3-dimethyl-2-imidazolidinone, N,N-dimethylacetamide, N,N-dimethylpropionamide, N,N-dimethylisobutylamide, N,N-diethylacetamide, N,N-dimethylformamide, N,N-diethylformamide, N,N-dimethylisobutyric acid amide, methoxy-N,N-dimethylpropionamide, butoxy-N,N-dimethylpropionamide, N-methylcaprolactam, N,N′-dimethylpropyleneurea, N,N,N′,N′-tetramethylurea, and pyridine; dimethyl sulfoxide; sulfolane; lactones, such as γ-butyrolactone, γ-valerolactone, δ-valerolactone, γ-caprolactone, ε-caprolactone, and α-methyl-γ-caprolactone; esters, such as methyl acetate, ethyl acetate, butyl acetate, and diethyl oxalate; carbonates, such as ethylene carbonate and propylene carbonate; ketones, such as acetone, methyl ethyl ketone, methyl isobutyl ketone, and cyclohexanone; acetonitrile; ethers, such as ethylene glycol dimethyl ether, diethylene glycol dimethyl ether, diethylene glycol diethyl ether, dioxane, and tetrahydrofuran; halogenated hydrocarbons, such as dichloromethane, 1,2-dichloroethane, 1,4-dichlorobutane, chlorobenzene, and o-dichlorobenzene; and hexane, heptane, benzene, toluene, and xylene. These organic solvents may be used alone, or two or more of these organic solvents may be used in combination.

In particular, the organic solvent is preferably a nitrogen-containing polar solvent, such as N-methyl-2-pyrrolidone, N,N-dimethylacetamide, N,N-diethylacetamide, N,N-dimethylformamide, N,N-diethylformamide, N-methylcaprolactam, or N,N,N′,N′-tetramethylurea.

The reaction of the tetracarboxylic dianhydride with the alcohol may be performed at any temperature that allows the reaction to proceed successfully. Typically, the reaction of the tetracarboxylic dianhydride with the alcohol is preferably performed at a temperature of −5° C. or more and 120° C. or less, more preferably 0° C. or more and 80° C. or less, even more preferably 0° C. or more and 50° C. or less. Typically, the reaction of the tetracarboxylic dianhydride with the alcohol is preferably performed for a time period of 30 minutes or more and 20 hours or less, more preferably 1 hour or more and 8 hours or less, even more preferably 2 hours or more and 6 hours or less, while the reaction time depends on the reaction temperature.

A small amount of a polymerization inhibitor may be used to prevent cross-linking between ethylenically unsaturated double bonds during the reaction of the tetracarboxylic dianhydride with the alcohol. Examples of such a polymerization inhibitor include phenols, such as hydroquinone, 4-methoxyphenol, tert-butylpyrocatechol, and bis-tert-butvlhydroxytoluene, and phenothiazines. For example, the polymerization inhibitor is preferably used in an amount of 0.01 mol % or more and 5 mcl % or less based on the number of moles of the ethylenically unsaturated double bond.

The reaction of the tetracarboxylic dianhydride with the alcohol may be performed in the presence of an organic base, such as pyridine, triethylamine, diisopropylethylamine, 4-dimethylaminopyridine, or 1,4-azabicyclo[2,2,2]octane. These bases may be used alone, or two or more of these bases may be used simultaneously.

The amount of the alcohol used for the reaction is preferably 1.8 moles or more and 2.2 moles or less, more preferably 2 moles or more and 2.1 moles or less, based on 1 mole of the tetracarboxylic dianhydride.

During the production of the dicarboxylic acid, some conditions may allow only one of the dicarboxylic anhydride groups to react with the alcohol to produce a monocarboxylic acid compound having the dicarboxylic anhydride group or may allow some of the tetracarboxylic dianhydride to react with water in the reaction system to produce a tetracarboxylic acid compound or a tricarboxylic acid compound. As long as the desired effect is not compromised, the dicarboxylic acid may be used together with at least one selected from such monocarboxylic, tricarboxylic, and tetracarboxylic acid compounds for the production of the polyamide macromonomer, the polyimide macromonomer, or the block copolymer. The polymerizable dicarboxylic acid product may contain at least one impurity selected from the group consisting of the monocarboxylic acid compound, the tricarboxylic acid compound, and the tetracarboxylic acid compound. In such a case, the content of the at least one impurity in the dicarboxylic acid product is preferably 30 mass % or less, more preferably 10 mass % or less, even more preferably 5 mass % or less, furthermore preferably 1 mass % or less, based on the mass of the dicarboxylic acid product containing the impurity.

### [Method for Producing Polyamide Macromonomer]

The polyamide macromonomer may be produced by any method capable of performing polycondensation of the diamine compound and the dicarboxylic acid until the weight average molecular weight of the resulting polyamide macromonomer increases to fall within the specified range. A preferred method includes condensing the diamine compound and the dicarboxylic acid in the presence of a condensing agent. If necessary, the condensing agent is preferably used together with a condensation aid. The condensing agent and the condensation aid may be any type used for the condensation of dicarboxylic acids and diamine compounds in the art.

The condensing agent is preferably at least one selected from the group consisting of dicyclohexylcarbodiimide, diisopropylcarbodiimide, 1-(3-dimethylaminopropyl)-3-ethylcarbodiimide, diisopropylcarbodiimide, 1-(3-dimethylaminopropyl)-3-ethylcarbodiimide hydrochloride, 1-cyclohexyl-3-(2-morpholinoethyl)-carbodiimide metho-toluenesulfonate, 1,3-bis(2,2-dimethyl-1,3-dioxolan-4-ylmethyl)carbodiimide, polymer-supported 1-benzyl-3-cyclohexylcarbodiimide, and polymer-supported 1-(3-dimethylaminopropyl)-3-ethylcarbodiimide.

The condensing agent may be used in any amount as long as the polyamide macromonomer can be obtained with a desired molecular weight. Typically, the condensing agent is preferably used in an amount of 1 mole or more and 5 moles or less, more preferably 2 moles or more and 4 moles or less, even more preferably 2 moles or more and 3 moles or less, based on 1 mole of the dicarboxylic acid. The amounts of the dicarboxylic acid and the diamine compound used for the production of the polyamide macromonomer may be in any ratio as long as the polyamide macromonomer can be produced with a desired molecular weight. For the production of the polyamide macromonomer having amino end groups, the raw material ratio represented by (the number of moles of the dicarboxylic acid or the tetracarboxylic dianhydride)/(the number of moles of the diamine compound) is preferably controlled within the range of 0.5/1 to 0.95/1, more preferably within the range of 0.55/1 to 0.80/1. As the ratio (the number of moles of the dicarboxylic acid or the tetracarboxylic dianhydride)/(the number of moles of the diamine compound) decreases, the molecular chain of the macromonomer becomes difficult to grow, and the resulting macromonomer tends to have a low molecular weight. For the production of the polyamide macromonomer having dicarboxylic anhydride end groups or carboxy end groups, the raw material ratio represented by (the number of moles of the diamine compound)/(the number of moles of the dicarboxylic acid or the tetracarboxylic dianhydride) is preferably controlled within the range of 0.5/1 to 0.95/1, more preferably within the range of 0.55/1 to 0.80/1. As the ratio (the number of moles of the diamine compound)/(the number of moles of the dicarboxylic acid or the tetracarboxylic dianhydride) decreases, the molecular chain of the macromonomer becomes difficult to grow, and the resulting macromonomer tends to have a low molecular weight.

Specifically, the dicarboxylic acid and the diamine compound may be allowed to react in the presence of the condensing agent in the organic solvent, for example, at a temperature of −20° C. or more and 150° C. or less, preferably 0° C. or more and 50° C. or less, for a time period of 30 minutes or more and 24 hours or less, preferably 1 hour or more and 4 hours or less.

Any of the solvents listed above for use in the reaction of the tetracarboxylic dianhydride with the alcohol may be used for the polycondensation. The solvent is preferably used in an amount of 50 parts by mass or more and 10,000 parts by mass or less, more preferably 100 parts by mass or more and 2,000 parts by mass or less, even more preferably 150 parts by mass or more and 1,000 parts by mass or less, based on 100 parts by mass of the total of the dicarboxylic acid and the diamine compound.

For the production of the polyamide macromonomer, the dicarboxylic acid and the diamine compound may be used in any suitable amounts. The amount of the diamine compound is preferably 0.8 moles or more and 1.2 moles or less, more preferably 0.9 moles or more and 1.1 moles or less, even more preferably 0.95 moles or more and 1.05 moles or less, based on 1 mole of the dicarboxylic acid.

The polyamide macromonomer produced as described above is used for the production of the block copolymer as is in the form of a solution or a suspension or after being separated and collected from the reaction liquid by well-known methods.

### [Polyimide Macromonomer]

The polyimide macromonomer is a polyamic acid macropolymer resulting from polymerization of a tetracarboxylic dianhydride and a diamine compound or a macromonomer resulting from imidization of the polyamide macromonomer. For example, the macromonomer may be heated so that imidization can proceed with elimination of the alcohol.

The polyamic acid macromonomer can be synthesized by a well-known method using a tetracarboxylic dianhydride and a diamine compound. The tetracarboxylic dianhydride described above as a raw material for the dicarboxylic acid for the polyamide macromonomer is preferably used for the production of the polyamic acid macromonomer. The diamine compound described above for the polyamide macromonomer is preferably used for the production of the polyamic acid macromonomer.

The polyamic acid macromonomer may be synthesized using any suitable amounts of the tetracarboxylic dianhydride and the diamine compound. The amount of the diamine compound is preferably 0.8 moles or more and 1.2 moles or less, more preferably 0.9 moles or more and 1.1 moles or less, even more preferably 0.95 moles or more and 1.05 moles or less, based on 1 mole of the tetracarboxylic dianhydride.

The reaction of the tetracarboxylic dianhydride with the diamine compound is usually performed in an organic solvent. The organic solvent used for the reaction of the tetracarboxylic dianhydride with the diamine compound may be any type that can dissolve the tetracarboxylic dianhydride and the diamine compound and will neither react with the tetracarboxylic dianhydride nor with the diamine compound. A single organic solvent may be used, or a mixture of two or more organic solvents may be used.

Examples of the organic solvent used for the reaction of the tetracarboxylic dianhydride with the diamine compound include nitrogen-containing polar solvents, such as N-methyl-2-pyrrolidone, N-ethyl-2-pyrrolidone, 1,3-dimethyl-2-imidazolidinone, N,N-dimethylacetamide, N,N-dimethylpropionamide, N,N-dimethylisobutylamide, N,N-diethylacetamide, N,N-dimethylformamide, N,N-diethylformamide, N,N-dimethylisobutyric acid amide, methoxy-N,N-dimethylpropionamide, butoxy-N,N-dimethylpropionamide, N-methylcaprolactam, N,N′-dimethylpropyleneurea, N,N,N′,N′-tetramethylurea, and pyridine; dimethyl sulfoxide; sulfolane; lactones, such as γ-butyrolactone, γ-valerolactone, δ-valerolactone, γ-caprolactone, ε-caprolactone, and α-methyl-γ-caprolactone; esters, such as methyl acetate, ethyl acetate, butyl acetate, and diethyl oxalate; carbonates, such as ethylene carbonate and propylene carbonate; ketones, such as acetone, methyl ethyl ketone, methyl isobutyl ketone, and cyclohexanone; acetonitrile; ethers, such as ethylene glycol dimethyl ether, diethylene glycol dimethyl ether, diethylene glycol diethyl ether, dioxane, and tetrahydrofuran; halogenated hydrocarbons, such as dichloromethane, 1,2-dichloroethane, 1,4-dichlorobutane, chlorobenzene, and o-dichlorobenzene; and hexane, heptane, benzene, toluene, and xylene. These organic solvents may be used alone, or two or more of these organic solvents may be used in combination.

In particular, for the solubility of the resulting polyamic acid macromonomer, the organic solvent is preferably a nitrogen-containing polar solvent, such as N-methyl-2-pyrrolidone, N,N-dimethylacetamide, N,N-diethylacetamide, N,N-dimethylformamide, N,N-diethylformamide, N-methylcaprolactam, or N,N,N′,N′-tetramethylurea.

The reaction of the tetracarboxylic dianhydride with the diamine compound may be performed at any temperature that allows the reaction to proceed successfully. Typically, the reaction of the tetracarboxylic dianhydride with the diamine compound is preferably performed at a temperature of −5° C. or more and 120° C. or less, more preferably 0° C. or more and 80° C. or less, even more preferably 0° C. or more and 50° C. or less. Typically, the reaction of the tetracarboxylic dianhydride with the diamine compound is preferably performed for a time period of 30 minutes or more and 20 hours or less, more preferably 1 hour or more and 12 hours or less, even more preferably 4 hours or more and 10 hours or less, while the reaction time depends on the reaction temperature.

During the production of the polyamic acid macromonomer by the method described above, some of the polyamic acid macromonomer may undergo ring closing and imidization. For the sake of convenience, the resulting resin with a degree of imidization of 50% or less may be used as the polyamic acid macromonomer, and the resulting resin with a degree of imidization of more than 50% may be used as the polyimide macromonomer.

In a case where the tetracarboxylic dianhydride and/or the diamine compound has a radically polymerizable group-containing group having an ethylenically unsaturated double bond, a small amount of a polymerization inhibitor may be used to prevent cross-linking between the ethylenically unsaturated double bonds during the reaction. Examples of such a polymerization inhibitor include phenols, such as hydroquinone, 4-methoxyphenol, tert-butylpyrocatechol, and bis-tert-butylhydroxytoluene, and phenothiazines. For example, the polymerization inhibitor is preferably used in an amount of 0.01 mol % or more and 5 mol % or less based on the number of moles of the ethylenically unsaturated double bond.

The method described above produces a solution containing the polyamic acid macromonomer. The resulting polyamic acid macromonomer may be ring-closed and imidized to a polyimide macromonomer. The imidization may be performed by any suitable method. The imidization may be performed by heating or using an imidizing agent.

The heating for imidization may be performed on a solution or suspension of the polyamic acid macromonomer or on the polyamic acid macromonomer in a solid state. For the imidization of a solution of the polyamic acid macromonomer, heating is preferably performed while water (a by-product of the imidization) is removed. The imidization may be performed under any conditions that do not decompose the polyamic acid macromonomer or the polyimide macromonomer and allow imidization to proceed successfully. Typically, a solution of the polyamic acid macromonomer is preferably heated at a temperature of 80° C. or more and 220° C. or less, more preferably 100° C. or more and 200° C. or less, even more preferably 120° C. or more and 180° C. or less. Typically, the polyamic acid macromonomer in a solid state is preferably heated at a temperature of 180° C. or more and 400° C. or less, more preferably 200° C. or more and 350° C. or less. Typically, the heating is preferably performed for a time period of 1 hour or more and 24 hours or less, more preferably 2 hours or more and 12 hours or less, while the heating time depends on the heating temperature. The polyimide macromonomer may be produced by heating the polyamide macromonomer in a manner similar to the heating of the polyamic acid.

The imidization using an imidizing agent usually includes adding the imidizing agent to a solution or suspension of the polyamic acid macromonomer to imidize it. For example, the imidization using an imidizing agent may be performed using the same organic solvent as that for the preparation of the polyamic acid macromonomer. For the imidization using an imidizing agent, the solution or suspension of the polyamic acid macromonomer may have any suitable concentration. Typically, the solution or suspension preferably has a polyamic acid macromonomer concentration of 5 mass % or more and 50 mass % or less, more preferably 10 mass % or more and 30 mass % or less. The imidizing agent may be used in any suitable amount. The amount of the imidizing agent is so selected as to achieve the desired degree of imidization of the polyamic acid macromonomer depending on the type of the imidizing agent. The imidization using the imidizing agent may be performed at any suitable reaction temperature. For example, the reaction temperature is preferably 0° C. or more and 100° C. or less, more preferably 5° C. or more and 50° C. or less. The imidization using the imidizing agent may be performed for any suitable reaction time. For example, the imidization reaction is preferably performed for a time period of about 30 minutes or more and about 24 hours or less, more preferably 1 hour or more and 12 hours or less, even more preferably 2 hours or more and 6 hours or less, depending on the type of the imidizing agent.

Examples of the imidizing agent include dehydrating agents, such as acetic anhydride, propionic anhydride, benzoic anhydride, trifluoroacetic anhydride, acetyl chloride, tosyl chloride, mesyl chloride, ethyl chloroformate, triphenyl phosphine and dibenzoimidazolyl disulfide, dicyclohexylcarbodiimide, carbodiimidazole, 2-ethoxy-1-ethoxycarbonyl-1,2-dihydroquinoline, and N,N′-disuccinimidyl oxalate; and basic compounds, such as pyridine, picoline, 2,6-lutidine, collidine, triethylamine, N-methylmorpholine, 4-N,N′-dimethylaminopyridine, isoquinoline, triethylamine, 1,4-diazabicyclo[2.2.2]octane, and 1,8-diazabicyclo[5.4.0]-7-undecene.

### <Method for Producing Block Copolymer>

The block copolymer is produced by copolymerization of: a macromonomer being a polyamide macromonomer and/or a polyimide macromonomer; a tetracarboxylic dianhydride and/or a dicarboxylic acid resulting from reaction of a tetracarboxylic dianhydride with an alcohol; and a diamine compound. The polyamide macromonomer and the polyimide macromonomer are as described above. The dicarboxylic acid resulting from reaction of a tetracarboxylic dianhydride with an alcohol is preferably one described above as a raw material for the polyamide macromonomer. The tetracarboxylic dianhydride is preferably one described above as a raw material for the dicarboxylic acid for the polyamide macromonomer.

The types and proportions of the structural units derived from the polyamide macromonomer and the polyimide macromonomer in the block copolymer are as described above. The block copolymer may be synthesized using any amounts of the tetracarboxylic dianhydride and/or the dicarboxylic acid and the diamine compound as long as the desired effect is not compromised. Typically, the diamine compound is preferably used in an amount of 0.8 moles or more and 1.2 moles or less, more preferably 0.9 moles or more and 1.1 moles or less, even more preferably 0.95 moles or more and 1.05 moles or less, based on 1 mole of the total of the tetracarboxylic dianhydride and/or the dicarboxylic acid.

In a case where the dicarboxylic acid is used, the block copolymer may be produced by a method similar to the method for producing the polyamide macromonomer. In this case, a condensing agent of the type shown above is preferably used in the amount shown above. Specifically, the block copolymer may be produced through allowing the dicarboxylic acid and the diamine compound to react in the presence of the condensing agent in an organic solvent, for example, at a temperature of −20° C. or more and 150° C. or less, preferably 0° C. or more and 50° C. or less, for a time period of 30 minutes or more and 24 hours or less, preferably 1 hour or more and 4 hours or less.

In a case where the tetracarboxylic dianhydride is used, the block copolymer may be produced by a method similar to the method for producing the polyamic acid. Specifically, the tetracarboxylic dianhydride and the diamine compound, and the polyamide macromonomer and/or the polyimide macromonomer are preferably allowed to react at a temperature of −5° C. or more and 120° C. or less, more preferably 0° C. or more and 80° C. or less, even more preferably 0° C. or more and 50° C. or less. Typically, the tetracarboxylic dianhydride and the diamine compound, and the polyamide macromonomer and/or the polyimide macromonomer are preferably allowed to react for a time period of 30 minutes or more and 20 hours or less, more preferably 1 hour or more and 8 hours or less, even more preferably 2 hours or more and 6 hours or less, while the reaction time depends on the reaction temperature.

For ease of having good dielectric properties in a high-frequency range, the block copolymer preferably contains a divalent aliphatic hydrocarbon group having 2 or more and 50 or less carbon atoms, more preferably 3 or more and 40 or less carbon atoms. The block copolymer may have such a divalent aliphatic hydrocarbon group at any suitable position in its molecular chain. The divalent aliphatic hydrocarbon group having 2 or more and 50 or less carbon atoms may be introduced into the molecular chain using a certain monomer such as the dimer diamine compound (A-4) or α,ω-bis(3,4-dicarboxyphenylcarbonyloxy)alkane dianhydride shown above.

The block copolymer may have any suitable weight average molecular weight depending on the intended use. The weight average molecular weight of the block copolymer may be determined as the polystyrene-equivalent weight average molecular weight by GPC (gel permeation chromatography). For example, to form a resin film having good mechanical properties, the block copolymer may have a polystyrene-equivalent weight average molecular weight of 5,000 or more, preferably 15,000 or more, more preferably 250,000,000 or more. On the other hand, for solubility in organic solvents, the resulting block copolymer may have a polystyrene-equivalent weight average molecular weight of 100,000 or less, preferably 80,000 or less, more preferably 50,000 or less. The weight average molecular weight can be adjusted to the value shown above by controlling reaction conditions, such as the contents of the tetracarboxylic dianhydride and/or the dicarboxylic acid and the diamine compound, the solvent, and the reaction temperature.

The ends of the main chain of the block copolymer may be blocked with a terminal blocking agent for the purpose of improving the storage stability of a resin film-forming composition containing the block copolymer or a polyimide resin derived from the block copolymer, for further improving the mechanical properties of a resin film including the block copolymer or a polyimide resin derived from the block copolymer, or for improving the reproducibility of polymerization for the production of the block copolymer. Examples of the terminal blocking agent include monoamines, acid anhydrides, monocarboxylic acids, mono-acid halides, and active mono-ester compounds. Monoamines for use as the terminal block agent may be known compounds. Examples of monoamines include aromatic monoamines, such as aniline, 2-ethynylaniline, 3-ethynylaniline, 4-ethynylaniline, 3-hydroxyaniline, 4-hydroxyaniline, 3-aminothiophenol, and 4-aminothiophenol; aliphatic monoamines optionally having a branched structure having 3 or more and 20 or less carbon atoms, such as hexylamine and octylamine; alicyclic structure-containing monoamines, such as cyclohexylamine; and aminosilanes, such as trimethoxyaminopropylsilane and triethoxyaminopropylsilane. As the terminal blocking agent, acid anhydrides are preferred to mono-acid halides and active mono-ester compounds. Known acid anhydrides and derivatives thereof may be used. Examples include phthalic anhydride, tetrahydrophthalic anhydride, hexahydrophthalic anhydride, xo-3,6-epoxy-1,2,3,6-tetrahydrophthalic anhydride, succinic anhydride, maleic anhydride, nadic anhydride, and derivatives thereof. Into the block copolymer, the terminal blocking agent is preferably introduced in a ratio of 40 mol % or less, more preferably 20 mol % or less, even more preferably 10 mol % or less, based on the number of moles of all monomers, for the production of a resin film having good mechanical properties from a resin film-forming composition containing the block copolymer or a polyimide resin derived from the block copolymer.

The block copolymer produced as described above may be used for a variety of applications as is or after being converted to a polyimide resin.

### <<Polyimide Resin>>

The block copolymer may be imidized to a polyimide resin. The polyimide resin has a molecular chain including a block derived from the polyimide macromonomer. Thus, the polyimide resin exhibits a low dielectric loss tangent in a high-frequency range and has good mechanical properties, such as high elongation and high strength. The block copolymer may be imidized by a method similar to the imidization of the polyamic acid macromonomer or the polyamide macromonomer described above.

### <<Resin Film-Forming Composition>>

The resin film-forming composition includes a resin (A) and a solvent (S). The resin (A) includes the block copolymer described above and/or the polyimide resin described above. By the method described later, the resin film-forming composition can be formed into a resin film including the block copolymer and/or the polyimide resin. The resulting resin film exhibits a low dielectric loss tangent in a high-frequency range and has good mechanical properties, such as high elongation and high strength.

As mentioned above, the block copolymer may have a radically polymerizable group. In such a case, the resin film-forming composition preferably contains a photo-radical polymerization initiator (C). The resin film-forming composition containing the photo-radical polymerization initiator (C) may also contain a radically polymerizable group-containing monomer compound (B).

Hereinafter, the essential and optional components of the resin film-forming composition will be described.

### <Resin (A)>

The resin (A) includes the block copolymer and/or the polyimide resin. The block copolymer and the polyimide resin are as described above.

### <Monomer Compound (B)>

The monomer compound (B) is preferably one having an ethylenically unsaturated double bond-containing radically polymerizable group. The monomer compound (B) with such a feature may be monofunctional or polyfunctional. Preferably, the monomer compound (B) is polyfunctional.

Examples of the monofunctional monomer compound include (meth)acrylamide, methylol(meth)acrylamide, methoxymethyl(meth)acrylamide, ethoxymethyl(meth)acrylamide, propoxymethyl(meth)acrylamide, butoxyethoxymethyl(meth)acrylamide, N-methylol(meth)acrylamide, N-hydroxymethyl(meth)acrylamide, (meth)acrylic acid, fumaric acid, maleic acid, maleic anhydride, itaconic acid, itaconic anhydride, citraconic acid, citraconic anhydride, crotonic acid, 2-acrylamido-2-methylpropanesulfonic acid, tert-butylacrylamide sulfonic acid, methyl (meth)acrylate, ethyl (meth)acrylate, butyl (meth)acrylate, 2-ethylhexyl (meth)acrylate, cyclohexyl (meth)acrylate, 2-hydroxyethyl (meth)acrylate, 2-hydroxypropyl (meth)acrylate, 2-hydroxybutyl (meth)acrylate, 2-phenoxy-2-hydroxypropyl (meth)acrylate, 2-(meth)acryloyloxy-2-hydroxypropyl phthalate, glycerol mono(meth)acrylate, tetrahydrofurfuryl (meth)acrylate, dimethylamino(meth)acrylate, glycidyl (meth)acrylate, 2,2,2-trifluoroethyl (meth)acrylate, 2,2,3,3-tetrafluoropropyl (meth)acrylate, and phthalic acid derivative half (meth)acrylate. These monofunctional photopolymerizable monomers may be used alone, or two or more of these monofunctional photopolymerizable monomers may be used in combination.

Examples of the polyfunctional monomer compound include ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, polypropylene glycol di(meth)acrylate, 1,3-butylene glycol di(meth)acrylate, 1,4-butylene glycol di(meth)acrylate, neopentyl glycol di(meth)acrylate, 1,6-hexane glycol di(meth)acrylate, 1,9-nonanediol di(meth)acrylate, 1,10-decanediol di(meth)acrylate, dimethyloltricyclodecane di(meth)acrylate, trimethyloloropane di(meth)acrylate, trimethylolpropane tri(meth)acrylate, trimethylolethane tri(meth)acrylate, trimethylolpropane tri(3-(meth)acryloyloxypropyl)ether, glycerol di(meth)acrylate, tri(meth)acrylates of glycerol ethylene oxide (EO) adducts, tri(meth)acrylates of glycerol propylene oxide (PO) adducts, tri(meth)acrylates of glycerol EO/PO co-adducts, tri(meth)acrylates of trimethylolpropane ethylene EO adducts, tri(meth)acrylates of trimethylolpropane PO adducts, tri(meth)acrylates of trimethylolpropane EO/PO co-adducts, tri(meth)acrylates of trimethylolethane EO adducts, tri(meth)acrylates of trimethylolethane PO adducts, tri(meth)acrylates of trimethylolethane EO/PO co-adducts, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, pentapentaerythritol dodeca(meth)acrylate, dimethylol-tricyclodecane di(meth)acrylate, 1,3-adamantanediol di(meth)acrylate, 1,3,5-adamantanetriol di(meth)acrylate, 1,3,5-adamantantanetriol tri(meth)acrylate, 1,4-cyclohexanedimethanol di(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth)acrylate, 9,9-bis[4-(2-(meth)acryloyloxyethoxy)phenyl]fluorene, 9,9-bis[4-(2-(meth)acryloyloxypropoxy)-3-methylphenyl]fluorene, 9,9-bis[4-(2-(meth)acryloyloxyethoxy)-3,5-dimethylphenyl]fluorene, ethylene glycol diglycidyl ether di(meth)acrylate, diethylene glycol diglycidyl ether di(meth)acrylate, diglycidyl phthalate di(meth)acrylate, glycerol triacrylate, glycerol polyglycidyl ether poly(meth)acrylate, urethane (meth)acrylate (i.e., tolylene diisocyanate), reaction products of trimethylhexamethylene diisocyanate, hexamethylene diisocyanate, and 2-hydroxyethyl (meth)acrylate acrylate, tri((meth)acryloyloxyethyl)isocyanurate, methylenebis(meth)acrylamide, (meth)acrylamide methvlene ether, condensation products of polyhydric alcohol and N-methylol(meth)acrylamide, and other polyfunctional monomer compounds, and triacrylformal. These polyfunctional monomer compounds may be used alone, or two or more of these polyfunctional monomer compounds may be used in combination.

Also preferably used are urethane (meth)acrylates shown in Japanese Examined Patent Application, Publication Nos. S48-41708 and S50-6034 and Japanese Unexamined Patent Application, Publication No. S51-37193; polyester (meth)acrylates shown in Japanese Unexamined Patent Application, Publication No. S48-64183 and Japanese Examined Patent Application, Publication Nos. S49-43191 and S52-30490; epoxy (meth)acrylates resulting from reaction of epoxy resin with (meth)acrylic acid; compounds shown in paragraphs [0254] to [0257] of Japanese Unexamined Patent Application, Publication No. 2008-292970; polyfunctional (meth)acrylates resulting from reaction of polyfunctional carboxylic acid with a compound having an epoxy group and an ethylenically unsaturated group, such as glycidyl (meth)acrylate; compounds or cardo resins having a fluorene ring and two or more ethylenically unsaturated bond-containing groups, shown in Japanese Unexamined Patent Application, Publication Nos. 2010-160418 and 2010-129825 and Japanese Patent No. 4364216; unsaturated compounds shown in Japanese Examined Patent Application, Publication Nos. S46-43946, H1-40337, and H1-40336; vinyl phosphonic acid compounds shown in Japanese Unexamined Patent Application, Publication No. H2-25493; perfluoroalkyl group-containing compounds shown in Japanese Unexamined Patent Application, Publication No. S61-22048; and photo-polymerizable monomers and oligomers shown in Journal of the Adhesion Society of Japan, Vol. 20, No. 7, pp. 300-308 (1984).

In particular, the ethylenically unsaturated double bond-containing monomer compound (B) is preferably a tri- or poly-functional monomer compound, more preferably a tetra- or poly-functional monomer compound, even more preferably a penta- or poly-functional monomer compound, because such a polyfunctional monomer compound tends to form a cured product having higher adhesion to substrates and higher strength.

The resin film-forming composition may contain any amount of the monomer compound (B) as long as the object of the present invention is not impaired. The content of the monomer compound (B) in the resin film-forming composition is preferably 0.1 parts by mass or more and 50 parts by mass or less, more preferably 0.5 parts by mass or more and 40 parts by mass or less, even more preferably 1 part by mass or more and 25 parts by mass or less, based on the mass calculated by subtracting the mass of the solvent (S) described later from the mass of the resin film-forming composition, which is normalized to 100 parts by mass.

### <Photo-Radical Polymerization Initiator (C)>

The resin film-forming composition preferably contains a photo-radical polymerization initiator (C) in a case where the resin (A) has a radically polymerizable group on its molecular chain or the resin film-forming composition contains the radically polymerizable group-containing monomer compound (B). The photo-radical polymerization initiator (C) may be any type, such as a conventionally known photopolymerization initiator.

Examples of the photo-radical polymerization initiator (C) include 1-hydroxycyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 2-hydroxy-1-{4-[4-(2-hydroxy-2-methyl-propionyl)-benzyl]phenyl}-2-methyl-propan-1-one, 1-(4-dodecylphenyl)-2-hydroxy-2-methylpropan-1-one, 2,2-dimethoxy-1,2-diphenylethan-1-one, bis(4-dimethylaminophenyl) ketone, 2-methyl-1-[4-(methylthio)phenyl]-2-morpholinopropan-1-one, 2-benzyl-2-dimethylamino-1-(4-morpholinophenyl)-butan-1-one, 2-(4-methylbenzyl)-2-dimethylamino-1-(4-morpholinophenyl)-butan-1-one, 1-phenyl-1,2-propanedione-2-(0-ethoxycarbonyl)oxime, 1-phenyl-1,2-propanedione-2-(O-methoxycarbonyl)oxime, 1-phenyl-2-(benzoyloximimino)-1-propanone, 1-phenyl-1,2-butadione-2-(o-methoxycarbonyl)oxime, 1,3-diphenylpropanetrione-2-(o-ethoxycarbonyl)oxime, ethanone,1-phenyl-1,2-propanedione-2-(O-benzoyl)oxime, 1-phenyl-3-ethoxypropanetrione-2-(O-benzoyl)oxime, O-acetyl-1-[6-(2-methylbenzoyl)-9-ethyl-9H-carbazol-3-yl]ethanone oxime (Irgacure OXE02 manufactured by BASF Japan), (9-ethyl-6-nitro-9H-carbazol-3-yl) [4-(2-methoxy-1-methylethoxy)-2-methylphenyl]methanone 0-acetyloxime, 1-[9-ethyl-6-(2-methylbenzoyl)-9H-carbazol-3-yl]-,1-(O-acetyloxime), 2-(benzoyloxyimino)-1-[4-(phenylthio)phenyl]-1-octanone (Irgacure OXE01 manufactured by BASF Japan), NCI-831 (manufactured by ADEKA Corporation), NCI-930 (manufactured by ADEKA Corporation), OXE-03 (manufactured by BASF Japan), OXE-04 (manufactured by BASF Japan), 2,4,6-trimethylbenzoyl diphenylphosphine oxide, bis(2,4,6-trimethylbenzoyl)-phenylphosphine oxide, bis(2,6-dimethoxybenzoyl)-2,4,4-trimethylpentylphosphine oxide, 4-benzoyl-4′-methyl dimethyl sulfide, 4-dimethylaminobenzoic acid, methyl 4-dimethylaminobenzoate, ethyl 4-dimethylaminobenzoate, butyl 4-dimethylaminobenzoate, 2-ethylhexyl 4-dimethylaminobenzoate, 2-isoamyl 4-dimethylaminobenzoate, ethyl 4-diethylbenzoate, benzyl-β-methoxyethyl acetal, benzyl dimethyl ketal, 1-phenyl-1,2-propanedione-2-(O-ethoxycarbonyl)oxime, methyl o-benzoylbenzoate, methyl benzoylformate, ethyl benzoylformate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, anthraquinone, 2-ethylanthraquinone, 2-tert-butylanthraquinone, octamethylanthraquinone, 2-aminoanthraquinone, β-chloroanthraquinone, 1,2-benzanthraquinone, 2,3-diphenylanthraquinone, anthrone, benzanthrone, dibenzosuberone, methyleneanthrone, azobisisobutyronitrile, benzoyl peroxide, cumene hydroperoxide, 2-mercaptobenzimidazole, 2-mercaptobenzoxazole, 2-mercaptobenzothiazole, 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, 4-hydroxybenzophenone, 4-phenylbenzophenone, fluorenone, benzil, benzoin, benzoin methyl ether, benzoin ethyl ether, benzoin isopropyl ether, benzoin n-butyl ether, benzoin isobutyl ether, acetophenone, 2,2-diethoxyacetophenone, p-dimethylacetophenone, p-dimethylaminopropiophenone, 2-hydroxy-2-methylpropiophenone, dichloroacetophenone, trichloroacetophenone, p-tert-butylacetophenone, 2-phenylacetophenone, p-dimethylaminoacetophenone, p-tert-butyltrichloroacetophenone, p-tert-butyldichloroacetophenone, α,α-dichloro-4-phenoxyacetophenone, thioxanthone, 2-methylthioxanthone, 2-isopropylthioxanthone, 2,4-dimethylthioxanthone, 2,4-diethylthioxanthone, 2-chlorothioxanthone, 2,4-dichlorothioxanthone, 2-hydroxy-3-(3,4-dimethyl-9-oxo-9H-thioxanthen-2-yloxy)-N,N,N-trimethyl-1-propanaminium chloride, 4-azidobenzalacetophenone, 2,6-bis (p-azidobenzylidene)cyclohexane, 2,6-bis(p-azidobenzylidene)-4-methylcyclohexanone, dibenzosuberone, pentyl-4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(furan-2-yl)ethenyl]-4,6-bis(trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine, 4-benzoyl-4′-methyldiphenyl ketone, dibenzyl ketone, 4-benzoyl-4′-methyl diphenyl sulfide, alkylated benzophenone, 3,3′,4,4′-tetra(tert-butylperoxycarbonyl)benzophenone, 4-benzoyl-N,N-dimethyl-N-[2-(1-oxo-2-propenyloxy)ethyl]benzenemethanaminium bromide, (4-benzoylbenzyl)trimethylammonium chloride, 2-hydroxy-3-(4-benzoylphenoxy)-N,N,N-trimethyl-1-propeneaminium chloride monohydrate, naphthalene sulfonyl chloride, quinoline sulfonyl chloride, N-phenylthioacridone, benzothiazole disulfide, triphenylphosphine, carbon tetrabromide, and tribromophenylsulfone. These photo-radical polymerization initiators (C) may be used alone, or two or more of these photo-radical polymerization initiators (C) may be used in combination. For good sensitivity, the photo-radical polymerization initiator (C) is preferably an oxime ester photopolymerization initiator.

In particular, in view of the sensitivity of the resin film-forming composition, the photo-radical polymerization initiator (C) is preferably an oxime ester compound. The oxime ester compound preferably has a partial structure of Formula (c1) below.

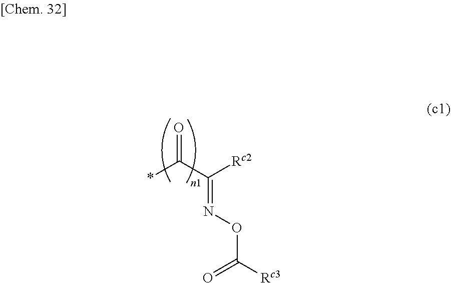

In Formula (c1), n1 is 0 or 1,

R^{c2} is a monovalent organic group,
R^{c3} is a hydrogen atom, an optionally substituted aliphatic hydrocarbon group having 1 or more and 20 or less carbon atoms, or an optionally substituted aryl group, and
* indicates a bond.

The resin film-forming composition may contain any amount of the photo-radical polymerization initiator (C) as long as the resin film-forming composition has desired photolithographic performance. Typically, the content of the photo-radical polymerization initiator (C) in the resin film-forming composition is 0.01 parts by mass or more and 20 parts by mass or less, more preferably 0.1 parts by mass or more and 15 parts by mass or less, even more preferably 1 part by mass or more and 10 parts by mass or less, based on 100 parts by mass of the total of the resin (A) and the monomer compound (B).

### <Solvent (S)>

The resin film-forming composition usually contains a solvent (S) for control of the ability to be applied and other purposes. The solvent (S) may be any type that can dissolve the resin (A) and the other components well. The solvent (S) is usually an organic solvent.

Examples of the solvent (S) for high solubility of the resin (A) include nitrogen-containing polar solvents, such as N,N-dimethylformamide, N,N-dimethylacetamide, N,N-diethylformamide, N-methyl-2-pyrrolidone, N-ethyl-2-pyrrolidone, hexamethylphosphoramide, 1,3-dimethyl-2-imidazolidinone, N,N-dimethylisobutyric acid amide, 3-methoxy-N,N-dimethylpropionamide, 3-butoxy-N,N-dimethylpropionamide, N,N-dimethylpropionamide, N,N-dimethylisobutylamide, and N,N-dimethylpropyleneurea; ketones, such as acetone, methyl ethyl ketone, methyl isobutyl ketone, 2-heptanone, 3-heptanone, diisobutyl ketone, cyclopentanone, cyclohexanone, and isophorone; γ-butyrolactone, γ-valerolactone, δ-valerolactone, γ-caprolactone, ε-caprolactone, α-methyl-γ-butyrolactone; esters, such as methyl lactate, ethyl lactate, methyl acetate, ethyl acetate, n-propyl acetate, n-butyl acetate, isobutyl acetate, isopentyl acetate, n-pentyl formate, n-butyl propionate, isopropyl butyrate, ethyl butyrate, n-butyl butyrate, methyl methoxyacetate, ethyl methoxyacetate, n-butyl methoxyacetate, methyl ethoxyacetate, ethyl ethoxyacetate, methyl 3-methoxypropionate, ethyl 3-methoxypropionate, methyl 3-ethoxypropionate, ethyl 3-ethoxypropionate, methyl 2-methoxypropionate, ethyl 2-methoxypropionate, methyl 2-ethoxypropionate, ethyl 2-ethoxypropionate, methyl 2-methoxy-2-methylpropionate, methyl 2-ethoxy-2-methylpropionate, methyl pyruvate, ethyl pyruvate, n-propyl pyruvate, methyl acetoacetate, ethyl acetoacetate, methyl 2-oxobutanoate, ethyl 2-oxobutanoate, propylene glycol monomethyl ether acetate, propylene glycol monoethyl ether acetate, propylene glycol monopropyl ether acetate, 3-methyl-3-methoxybutyl acetate, methyl cellosolve acetate, and ethyl cellosolve acetate; alcohols, such as diacetone alcohol and 3-methyl-3-methoxybutanol; glycol ethers, such as ethylene glycol monomethyl ether, ethylene glycol monoethyl ether, propylene glycol monomethyl ether, propylene glycol monoethyl ether, diethylene glycol monomethyl ether, diethylene glycol monoethyl ether, diethylene glycol mono-n-butyl ether, and diethylene glycol dimethyl ether; aromatic ethers, such as anisole; cyclic ethers, such as dioxane and tetrahydrofuran; cyclic esters, such as ethylene carbonate and propylene carbonate; aromatic solvents, such as anisole, toluene, and xylene; aliphatic hydrocarbons, such as limonene; and sulfoxides, such as dimethyl sulfoxide.

The solvent (S) may be used in any amount sufficient to form the resin film-forming composition in a uniform liquid state. The resin film-forming composition may be a suspension or a solution. Preferably, the resin film-forming composition is a solution. Typically, the solvent (S) is preferably used in such an amount that the resulting resin film-forming composition has a solids concentration of 15 mass % or more and 50 mass % or less, more preferably 20 mass % or more and 45 mass % or less.

### <Additional Components>

If necessary, the resin film-forming composition may contain various additives in addition to the components described above. Examples of the additive include a coloring agent, a dispersing agent, a sensitizing agent, an adhesion promoting agent, a polymerization inhibitor, an antioxidizing agent, an ultraviolet absorbing agent, an aggregation preventing agent, a defoaming agent, a surfactant, an imidization promoting agent, a nitrogen-containing heterocyclic compound for serving as an adhesion improving agent, and a silane coupling agent. If necessary, the photosensitive resin composition may also contain various fillers or reinforcing materials.

The sensitizing agent may be a known compound. Examples of the sensitizing agent include bis(dimethylamino)benzophenone, bis(diethylamino)benzophenone, diethvlthioxanthone, N-phenyldiethanolamine, N-phenylglycine, 7-diethvlamino-3-benzoylcoumarin, 7-diethylamino-4-methylcoumarin, N-phenylmorpholine, and derivatives thereof.

The polymerization inhibitor may be a known compound. Examples of the polymerization inhibitor include phenolic hydroxyl group-containing compounds, nitroso compounds, N-oxide compounds, quinone compounds, N-oxyl compounds, and phenothiazine compounds. More specifically, the polymerization inhibitor is preferably Irganox 1010, Irganox 1035, Irganox 1098, Irganox 1135, Irganox 245, Irganox 259, Irganox 3114 (all manufactured by BASF Japan), 2,6-di-tert-butyl-p-cresol, or 4-methoxyphenol, more preferably Irganox 1010, 2,6-di-tert-butyl-p-cresol, or 4-methoxyphenol.

In a case where the resin film-forming composition contains the photo-radical polymerization initiator (C), the resin film-forming composition preferably contains 0.005 mass % or more and 1 mass % or less, more preferably 0.01 mass % or more and 0.5 mass % or less, even more preferably 0.03 mass % or more and 0.3 mass % or less of the polymerization inhibitor based on the mass of the resin (A) so that the resin film-forming composition can have both high developability and high oxidation resistance.

The nitrogen-containing heterocyclic compound can coordinate with metal surfaces to stabilize thereon. Thus, the resin film-forming composition containing it can form a resin film having improved adhesion to metal surfaces. The nitrogen-containing heterocyclic compound may be a known compound. Examples of the nitrogen-containing heterocyclic compound include imidazole, pyrazole, indazole, carbazole, triazole, pyrazoline, pyrazolidine, tetrazole, pyridine, piperidine, pyrimidine, pyrazine, triazine, cyanuric acid, isocyanuric acid, and derivatives thereof. Preferred examples of the nitrogen-containing heterocyclic compound with a high ability to coordinate with metal include triazoles, such as 1H-benzotriazole, 4-methyl-1H-methylbenzotriazole, 5-methyl-1H-methylbenzotriazole, 4-carboxy-1H-methylbenzotriazole, and 5-carboxy-1H-methylbenzotriazole; and tetrazoles, such as 1H-tetrazole, 5-methyl-1H-tetrazole, and 5-phenyl-1H-tetrazole.

In a case where the resin film-forming composition contains the photo-radical polymerization initiator (C), the resin film-forming composition preferably contains 0.01 mass % or more and 5 mass % or less, more preferably 0.05 mass % or more and 3 mass % or less of the nitrogen-containing heterocyclic compound based on the mass of the resin (A) so that the resin film-forming composition can not only have high developability but also form a resin film with improved adhesion to substrates and other materials.

When the resin film-forming composition contains a silane coupling agent, it can form a resin film with improved adhesion to substrates and other materials. The silane coupling agent may be a known compound. Examples of the silane coupling agent include 3-aminopropyltrimethoxysilane, 3-aminopropyltriethoxysilane, vinyltrimethoxysilane, vinyltriethoxysilane, 3-mercaptopropyltrimethoxysilane, 3-mercaptopropyltriethoxysilane, 3-glycidoxypropyltrimethoxysilane, 3-glycidoxypropyltriethoxysilane, 2-(epoxycyclohexyl)ethyltrimethoxysilane, 2-(epoxycyclohexyl)triethoxysilane, tris(3-trimethoxysilylpropyl)isocyanurate, tris(3-triethoxysilvlpropyl)isocyanurate, reaction products of 3-aminopropyltrimethoxysilane and acid anhydride, and reaction products of 3-aminopropyltriethoxysilane and acid anhydride. Examples of the acid anhydride to react with 3-aminopropyltrimethoxysilane or 3-aminopropyltriethoxysilane include succinic anhydride, maleic anhydride, nadic anhydride, 3-hydroxyphthalic anhydride, pyromellitic dianhydride, 3,3′,4,4′-biphenyltetracarboxylic dianhydride, 2,2′,3,3′-benzophenonetetracarboxylic dianhydride, and 4,4′-oxydiphthalic dianhydride.

The resin film-forming composition preferably contains 0.01 mass' or more and 10 mass % or less of the silane coupling agent based on the mass of the resin (A).

When the resin film-forming composition contains a surfactant, it can have improved ability to be applied and improved wettability on the substrate. The surfactant may be a known compound. Examples of the surfactant include fluorinated surfactants, nonionic surfactants, cationic surfactants, anionic surfactants, and silicone surfactants.

The resin film-forming composition preferably contains 0.001 mass % or more and 1 mass % or less of the surfactant based on the mass of the resin (A).

In a case where the resin (A) can be converted to a polyimide resin by heating, the resin film-forming composition may contain a cyclization promoting agent. The cyclization promoting agent accelerates the formation of the polyimide resin by promoting the cyclization of the polyamide resin having a structural unit derived from the polyamic acid or the dicarboxylic acid compound, which can be synthesized by the reaction of the tetracarboxylic dianhydride with the alcohol. When the resin film-forming composition contains the cyclization promoting agent, it can form a resin film containing polyimide resin produced by the cyclization and having improved mechanical properties and improved weather resistance reliability. The cyclization promoting agent may be a known thermal base generating agent or a known thermal acid generating agent.

The resin film-forming composition may contain any amounts of various additives as long as the object of the present invention is not impaired. The content of the additives for which no content is specified above may be adjusted as appropriate, for example, within the range of 0.001 mass % or more and 60 mass % or less, preferably within the range of 0.01 mass % or more and 5 mass % or less, based on the mass of the solids in the resin film-forming composition.

### <Method for Preparing the Resin Film-Forming Composition>

The essential components described above and, if necessary, the optional components described above may be uniformly mixed in desired amounts to form a photosensitive resin composition. The mixing may be performed by any suitable method. The resin film-forming composition is preferably filtered through a filter for the purpose of removing foreign matter from the resin film-forming composition.

### <<Photosensitive Dry Film>>

A photosensitive dry film is provided, including: a base film; and a photosensitive layer provided on a surface of the base film, in which the photosensitive layer is made from the resin film-forming composition containing the photo-radical polymerization initiator (C).

The base film is preferably one having optical transparency. Examples of the base film include a polyethylene terephthalate (PET) film, a polypropylene (PP) film, and a polyethylene (PE) film, among which a polyethylene terephthalate (PET) film is preferred since it has a good balance between optical transparency and rupture strength.

The photosensitive dry film is produced by applying the resin film-forming composition onto the base film to form a photosensitive layer. For the formation of the photosensitive layer on the base film, the resin film-forming composition is applied onto the base film using an applicator, a bar coater, a wire bar coater, a roll coater, a curtain flow coater, or any other coater such that a film can be formed preferably with a dry thickness of 0.5 μm or more and 300 μm or less, more preferably with a dry thickness of 1 μm or more and 300 μm or less, even more preferably with a dry thickness of 3 μm or more and 100 μm or less, on the base film, and then dried.

The photosensitive dry film may further include a protective film on the photosensitive layer. The protective film may be a polyethylene terephthalate (PET) film, a polypropylene (PP) film, or a polyethylene (PE) film.

### <<Resin Film Forming Method>>

A resin film can be formed by a method including:

applying the resin film-forming composition onto a substrate to form a coating; and
drying the coating to form a resin film.

The substrate may be any type, such as a conventionally known substrate, examples of which include substrates for electronic parts and substrates having specific wiring patterns. The substrate may also be a silicon substrate, a glass substrate, or any other material.

Applying the resin film-forming composition in a liquid state onto the substrate to form a coating is followed by removing the solvent from the coating of the resin film-forming composition to form a coating film with a desired thickness. The thickness of the coating film is preferably, but not limited to, 0.5 μm or more, more preferably 0.5 μm or more and 300 μm or less, even more preferably 1 μm or more and 150 μm or less, most preferably 3 μm or more and 100 μm or less.

The resin film-forming composition may be applied onto the substrate by spin coating, slit coating, roll coating, screen printing, applicator method, or any other coating method.

The coating of the resin film-forming composition on the substrate may be dried by any suitable method. Preferably, the drying is performed by heating. The heating conditions for the drying are generally at 70° C. or more and 200° C. or less, preferably at 80° C. or more and 150° C. or less, for about 2 minutes or more and about 120 minutes or less while they depend on the type and proportion of each component in the resin film-forming composition, the thickness of the coating, and other factors. The process described above forms a resin film including the block copolymer or the polyimide resin derived from the block copolymer.

### <<Method of Forming Patterned Resin Film>>

A patterned resin film is formed by a method including: applying, onto a substrate, the resin film-forming composition containing: the block copolymer having the radically polymerizable group; and the photo-radical polymerization initiator (C) to form a coating;

subjecting the coating to positionally selective exposure to an active ray or a radiation; and
developing the exposed coating to form a patterned resin film.

This method is preferably performed using the resin film-forming composition including: the photo-radical polymerization initiator (C); and the block copolymer including a block derived from the polyamide macromonomer resulting from polymerization of the diamine compound and the dicarboxylic acid resulting from reaction of the tetracarboxylic dianhydride with the radically polymerizable group-containing alcohol.

The substrate and the method for applying the resin film-forming composition are as described above for the resin film forming method. The coating of the resin film-forming composition on the substrate is usually dried to form a coating film. The coating of the resin film-forming composition on the substrate may be dried by any suitable method. Preferably, the drying is performed by heating. The heating conditions for the drying are generally at 70° C. or more and 200° C. or less, preferably at 80° C. or more and 150° C. or less, for about 2 minutes or more and about 120 minutes or less while they depend on the type and proportion of each component in the resin film-forming composition, the thickness of the coating, and other factors.

The resulting coating film is subjected to positionally selective exposure to an active ray or a radiation. The positionally selective exposure is usually performed by applying, to the coating film, an active ray or a radiation (e.g., ultraviolet or visible light with a wavelength of 300 nm or more and 500 nm or less) in a positionally selective manner through a mask with a specific pattern.

The radiation source may be a low-pressure mercury lamp, a high-pressure mercury lamp, an ultra-high pressure mercury lamp, a metal halide lamp, an argon gas laser, or any other radiation source. Examples of the radiation include microwaves, infrared rays, visible rays, ultraviolet rays, X-rays, γ-rays, electron beams, proton beams, neutron beams, ion beams, and so on. The radiation dose depends on the make-up of the resin film-forming composition, the thickness of the photosensitive layer, and other factors. In a case where an ultra-high pressure mercury lamp is used, for example, the radiation dose may be 100 mJ/cm² or more and 10,000 mJ/cm² or less.

The exposed coating film is then developed by conventionally known methods, which dissolve and remove unnecessary portions and form a resin film with a specific pattern. This process is performed using a developing liquid selected depending on the components in the resin film-forming composition. In a case where the block copolymer is a resin having alkali-soluble groups, such as carboxy groups, the developing liquid may be an alkaline aqueous solution. In a case where the resin film-forming composition includes a combination of the radically polymerizable group-containing resin and the photo-radical polymerization initiator (C), the developing liquid may be the solvent (S) described above.

Examples of alkaline developing liquids include aqueous solutions containing an alkali, such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, dimethylethanolamine, triethanolamine, tetramethylammonium hydroxide (tetramethylammonium hydroxide), tetraethylammonium hydroxide, pyrrole, piperidine, 1,8-diazabicyclo[5,4,0]-7-undecene, or 1,5-diazabicyclo[4,3,0]-5-nonane. The developing liquid may also be an aqueous solution containing the alkali and appropriate amounts of a water-soluble organic solvent, such as methanol or ethanol, and a surfactant.

The developing time is usually 1 minute or more and 30 minutes or less while it depends on the make-up of the resin film-forming composition, the thickness of the coating film, and other factors. The developing method may be a liquid filling method, a dipping method, a paddle method, a spray development method, or any other suitable method.

After the development, cleaning is performed as needed for a time period of 30 seconds or more and 90 seconds or less, and the patterned resin film is dried using an air gun, an oven, or other means. In this way, a resin film with a desired pattern is formed on the surface of the substrate. The cleaning solvent may be any suitable type. As an example, the cleaning solvent may be water or an alcohol in the case of alkali development. In the case of solvent (S) development, the solvent (S) may be used for the cleaning as long as it causes no solvent shock.

In a case where the block copolymer in the resin film is imidizable, if necessary, the development may be followed by baking the developed coating film to imidize the block copolymer in the film. Heating the block copolymer to convert it to a polyimide resin may be performed under the conditions described above. For the formation of a resin film having good mechanical properties without oxidation thereof, the baking is preferably performed under an inert gas atmosphere, such as nitrogen or argon.

The resulting patterned resin film is suitable for use as, for example, an insulating film for semiconductor devices, an interlayer insulating film for rewiring layers, or an insulating or protective film for touch panel displays and organic electroluminescent display panels. The photosensitive resin composition described above has good resolution. Thus, in particular, the resulting patterned resin film can be advantageously used as an interlayer insulating film for rewiring layers in three-dimensionally mounted devices. The resulting patterned resin film is also suitable for use as a photoresist, galvanic (electrolytic) resist, etching resist, or solder top resist for electronics. Moreover, the resulting patterned resin film can also be used for the production of printing plates, such as offset plates and screen printing plates, for the formation of etching masks for use in etching molded components, and for the production of protective lacquers and dielectric layers for electronic parts, specifically, microelectronic parts.

### EXAMPLES

Hereinafter, the present invention will be described in more detail with reference to examples, which are not intended to limit the scope of the present invention.

Examples 1 to 29 and Comparative Examples 1 to 3 were performed using diamine compounds DA1 to DA6 below. DA6 corresponds to the compound of Formula (32) above.

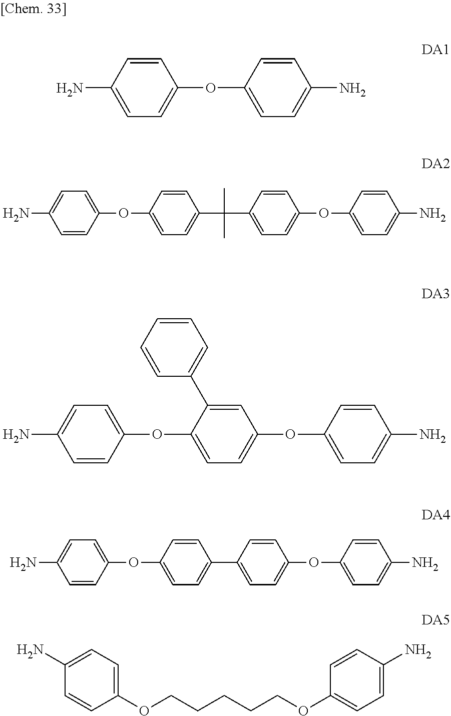 [SMILES: Nc1ccc(Oc2ccc(N)cc2)cc1 ; CC(C)(c1ccc(Oc2ccc(N)cc2)cc1)c1ccc(Oc2ccc(N)cc2)cc1 ; Nc1ccc(Oc2ccc(Oc3ccc(N)cc3)c(-c3ccccc3)c2)cc1 ; Nc1ccc(Oc2ccc(-c3ccc(Oc4ccc(N)cc4)cc3)cc2)cc1 ; Nc1ccc(OCCCCCOc2ccc(N)cc2)cc1]

### Example 1

### (Production of Polyimide Macromonomer)

In 63.2 g of NMP (N-methyl-2-pyrrolidone) was dissolved 26.63 g (0.133 moles) of DA1. Subsequently, 52.22 g (0.10 moles) of 10BTA (1,10-bis(3,4-dicarboxyphenylcarbonyloxy)decane dianhydride) was added to the resulting solution. While being heated at 40° C., the resulting solution was stirred for 2 hours to produce a polyamic acid macromonomer solution. After 20 g of toluene was added to the resulting polyamic acid macromonomer solution, the mixture was stirred at 180° C. for 4 hours while water, a by-product of the ring-closing reaction, was azeotropically removed by refluxing toluene using a dean-stark apparatus. Subsequently, the toluene was removed by distillation, so that a solution of a polyimide macromonomer having amino end groups was obtained. As a result of analysis by gel permeation chromatography, the resulting polyimide macromonomer was found to have a weight average molecular weight of 15,000.

### (Production of Block Copolymer)

In 300 g of NMP was dispersed 124.1 g (0.4 moles) of 4,4′-oxydiphthalic anhydride. To the resulting dispersion was added 109.3 g (0.84 moles) of 2-hydroxyethyl methacrylate and 66.44 g (0.84 moles) of pyridine. The dispersion was then stirred at room temperature for 14 hours to produce a solution of a dicarboxylic acid having two 2-(2-methacryloyloxy)ethoxycarbonyl groups, which resulted from the reaction of 4,4′-oxydiphthalic anhydride with 2-hydroxyethyl methacrylate. The resulting dicarboxylic acid solution was cooled with ice. To the cooled solution was added 128.6 g (0.84 moles) of 1-hydroxybenzotriazole monohydrate and 173.3 g (0.84 moles) of DCC (dicyclohexylcarbodiimide), and the resulting solution was cooled with ice and stirred for 30 minutes. Subsequently, the polyimide macromonomer solution previously obtained and a solution of 73.42 g (0.37 moles) of DA1 in 200 g of NMP were added to the solution containing the dicarboxylic acid, 1-hydroxybenzotriazole monohydrate, and DCC. The resulting mixture was stirred at room temperature for 6 hours. Subsequently, 60.0 g of methanol was added to the mixture and stirred to form a precipitate. After the precipitate was removed by filtration, the resulting filtrate was added dropwise into an isopropyl alcohol aqueous solution to produce a resin precipitate. The resulting resin was washed three times with isopropyl alcohol to give a polyamide resin, which resulted from the copolymerization with the polyimide macromonomer. As a result of analysis by gel permeation chromatography, the resulting polyamide resin was found to have a weight average molecular weight of 40,000. The resulting chart was unimodal, and it was confirmed that the resulting polyamide resin was a block copolymer resulting from the copolymerization with the polyimide macromonomer.

A resin film-forming photosensitive composition was obtained by dissolving the resulting block copolymer at a concentration of 30 mass % in γ-butyrolactone and then adding, to the resulting solution, 5 mass % of an oxime ester initiator (Irgacure OXE02 (BASF Japan)), 0.05 mass % of a polymerization inhibitor (Irganox 1010 (BASF Japan)), 0.02 mass % of a surfactant (POLYFLOW NO. 77 (Kyoeisha Chemical Co., Ltd.)), and 3 mass % of N-[3-(triethoxysilyl)propyl]phthalic acid amide based on the mass of the block copolymer.

A resin film was formed by the method shown below using the resulting resin film-forming composition. The resulting resin film was evaluated for dielectric loss tangent and elongation. It should be noted that the block copolymer in the resulting resin film includes a block derived from the polyimide macromonomer. As a result, the dielectric loss tangent, elongation, and strength of the resin film were all evaluated as “O”.

### <Evaluation of Dielectric Loss Tangent>

The resin film-forming composition was applied onto a silicon wafer using a spin coater. The resulting thin film of the resin film-forming composition was baked at 90° C. for 240 seconds. The baked film was exposed to light at a total dose of 2,000 mJ/cm² from a high-pressure mercury lamp. In an inert oven, the exposed film was heated to 230° C. at a rate of temperature increase of 5° C./minute under a nitrogen atmosphere and then heated at 230° C. for 1 hour. When the temperature dropped to 100° C., the wafer was removed and immersed in a 2 wt % hydrofluoric acid aqueous solution for 5 to 30 minutes, so that the resin film was removed from the wafer. The resulting resin film was a film of a polyimide resin resulting from the ring-closing imidization of the block copolymer. The removed resin film had a thickness of 10 μm.

The dielectric loss tangent (tan δ) of the resulting film was measured by the method described in IEICE Technical Report, Vol. 118, No. 506, MW2018-158, pp. 13-18, March 2019, “Study on Evaluation of Millimeter-Wave Complex Permittivity of Photosensitive Insulating Film by Cylindrical Cavity Resonator Method” (Kohei Takahagi (Utsunomiya University), Kazuaki Ebisawa (Tokyo Ohka Kogyo Co., Ltd.), Yoshinori Kogami (Utsunomiya University), Takashi Shimizu (Utsunomiya University). The measurement was performed by cavity resonator method using Network Analyzer HP8510C (manufactured by Keysight Technologies) under the conditions of a room temperature of 25° C., a humidity of 50%, a frequency of 36 GHz, and a sample thickness of 10 μm. The measured dielectric loss tangent was evaluated according to the criteria below. O: The measured dielectric loss tangent is less than 0.012. X: The measured dielectric loss tangent is 0.012 or more.

### <Tensile Test (Elongation)>

A film was obtained as in the evaluation of the dielectric loss tangent. The resulting film was cut into test strips with a width of 1 cm and a length of 5 cm. The test strips were subjected to a tensile test using a tensile tester (EZ Test manufactured by Shimadzu Corporation) under the conditions of a chuck-chuck distance of 2 cm and a tensile speed of 1 mm/minute, in which their tensile elongation was determined. The tensile elongation was calculated from the equation below. Tensile elongation (%)={(chuck-chuck distance (cm) at break)/2 (cm)−1}×100 The tensile elongation was evaluated as “O” when it was 30% or more, and as “X” when it was less than 30%.

### <Tensile Test (Strength)>

A film was obtained as in the evaluation of the dielectric loss tangent. The resulting film was cut into test strips with a width of 1 cm and a length of 5 cm. The test strips were subjected to a tensile test using a tensile tester (EZ Test manufactured by Shimadzu Corporation) under the conditions of a chuck-chuck distance of 2 cm and a tensile speed of 1 mm/minute, in which their maximum stress was determined. The test strip with a maximum stress of 100 MPa or more during the test was evaluated as “O” for strength, and the test strip with a maximum stress of less than 100 MPa during the test was evaluated as “X” for strength.

### Example 2

A resin film-forming composition was obtained as in Example 1 except that the amount of DA1 for the production of the polyimide macromonomer was changed to 30.83 g (0.154 moles) and the amount of DA1 for the production of the block copolymer was changed to 69.31 g (0.346 moles). The polyimide macromonomer used for the production of the block copolymer had a polystyrene-equivalent weight average molecular weight of 7,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 3

A resin film-forming composition was obtained as in Example 1 except that the amount of DA1 for the production of the polyimide macromonomer was changed to 33.38 g (0.167 moles) and the amount of DA1 for the production of the block copolymer was changed to 66.74 g (0.333 moles). The polyimide macromonomer used for the production of the block copolymer had a polystyrene-equivalent weight average molecular weight of 3,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 4

A resin film-forming composition was obtained as in Example 1 except that 26.63 g (0.133 moles) of DA1 for the production of the polyimide macromonomer was changed to 0.133 moles of DA2 and 73.42 g (0.37 moles) of DA1 for the production of the block copolymer was changed to 0.37 moles of DA2. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 5

A resin film-forming composition was obtained as in Example 1 except that 124.1 g (0.4 moles) of 4,4′-oxydiphthalic anhydride for the production of the block copolymer was changed to 0.4 moles of 3,3′,4,4′-biphenyltetracarboxylic dianhydride. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 6

A resin film-forming composition was obtained as in Example 1 except that 26.63 g (0.133 moles) of DA1 for the production of the polyimide macromonomer was changed to 0.133 moles of DA2, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA2. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 7

A resin film-forming composition was obtained as in Example 1 except that 124.1 g (0.4 moles) of 4,4′-oxydiphthalic anhydride for the production of the block copolymer was changed to 0.4 moles of 2,2-bis[4-(3,4-dicarboxyphenyloxy)phenyl]propane dianhydride. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 8

A resin film-forming composition was obtained as in Example 1 except that 26.63 g (0.133 moles) of DA1 for the production of the polyimide macromonomer was changed to 0.133 moles of DA3 and 73.42 g (0.37 moles) of DA1 for the production of the block copolymer was changed to 0.37 moles of DA3. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 9

A resin film-forming composition was obtained as in Example 1 except that 26.63 g (0.133 moles) of DA1 for the production of the polyimide macromonomer was changed to 0.133 moles of DA4 and 73.42 g (0.37 moles) of DA1 for the production of the block copolymer was changed to 0.37 moles of DA5. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Example 10

A resin film-forming composition was obtained as in Example 1 except that 26.63 g (0.133 moles) of DA1 for the production of the polyimide macromonomer was changed to 0.133 moles of DA4, 52.22 g (0.10 moles) of 10BTA for the production of the polyimide macromonomer was changed to 0.10 moles of 2,2-bis[4-(3,4-dicarboxyphenyloxy)phenyl]propane dianhydride, and 73.42 g (0.37 moles) of DA1 for the production of the block copolymer was changed to 0.37 moles of DA5. The polyimide macromonomer used for the production of the block copolymer had a polystyrene-equivalent weight average molecular weight of 15,000 as measured by gel permeation chromatography. The block copolymer had a polystyrene-equivalent weight average molecular weight of 40,000 as measured by gel permeation chromatography. The resulting resin film-forming composition was evaluated for dielectric loss tangent and elongation as in Example 1. The block copolymer in the resin film was found to have undergone imidization by baking. As a result, the dielectric loss tangent, elongation, and strength of the resin film were all evaluated as “O”.

### Comparative Example 1

In 69 g of NMP were dispersed 24.82 g (0.08 moles) of 4,4′-oxydiohthalic dianhvdride and 10.44 g (0.02 moles) of 10BTA. To the resulting dispersion were added 26.03 g (0.20 moles) of 2-hydroxyethyl methacrylate (HEMA), 15.82 g (0.20 moles) of pyridine, and 2.443 g (0.02 moles) of dimethylaminopyridine. The resulting mixture was then stirred at room temperature for 16 hours to produce a mixture of di-2-methacryloyloxyethyl ester of 4,4′-oxydiphthalic acid and di-2-methacryloyloxyethyl ester of tetracarboxylic acid derived from 10BTA. The resulting dicarboxylic acid solution containing 0.1 moles of the diester mixture was cooled to 0° C. Subsequently, a solution including 42.30 g (0.21 moles) of dicyclohexylcarbodiimide and 42 g of NMP, 43.33 g (0.21 moles) of 1-hydroxybenzotriazole monohydrate, and a diamine solution including 20.02 g (0.10 moles) of DA1 shown above and 43 g of NMP were added dropwise into the dicarboxylic acid solution. After the dropwise addition was completed, the resulting reactive liquid was stirred at room temperature for 4 hours to undergo condensation reaction. After the reaction was completed, 19.7 g of methanol was injected into the reaction liquid. The resulting precipitate was removed by filtration, so that the reaction liquid was obtained. The resulting reaction liquid was added dropwise into an isopropyl alcohol aqueous solution to precipitate a brown polyamide resin powder. The precipitated powder was collected by filtration and then washed three times with isopropyl alcohol. The washed powder was dried under reduced pressure to give a polyamide resin resulting from polycondensation of: di-2-methacryloyloxyethyl ester of 4,4′-oxydiphthalic acid; di-2-methacryloyloxyethyl ester of tetracarboxylic acid derived from 10BTA; and DA1 shown above. The resulting polyamide resin has a 2-(methacryloyloxy)ethoxycarbonyl group, which is a radically polymerizable group. The resulting polyamide resin had a polystyrene-equivalent weight average molecular weight of 40,000 as measured by gel permeation chromatography. A resin film-forming composition was obtained and evaluated for dielectric loss tangent and elongation as in Example 1. As a result, the resin film was evaluated as “O” for dielectric loss tangent, as “X” for elongation, and as “X” for strength.

### Comparative Example 2

A polyamide resin was obtained as in Comparative Example 1 except that the mixture of 24.82 g (0.08 moles) of 4,4′-oxydiphthalic dianhydride and 10.44 g (0.02 moles) of 10BTA was changed to 0.10 moles of 4,4′-oxydiphthalic dianhydride and 20.02 g (0.10 moles) of DA1 was changed to a mixture of 0.08 moles of DA1 and 0.02 moles of DA6 (the compound of Formula (32) above). The resulting polyamide resin has a 2-(methacryloyloxy)ethoxycarbonyl group, which is a radically polymerizable group. The resulting polyamide resin had a polystyrene-equivalent weight average molecular weight of 45,000 as measured by gel permeation chromatography. A resin film-forming composition was obtained and evaluated for dielectric loss tangent and elongation as in Example 1. As a result, the resin film was evaluated as “O” for dielectric loss tangent, as “X” for elongation, and as “X” for strength.

### Comparative Example 3

A polyamide resin was obtained as in Comparative Example 1 except that the mixture of 24.82 g (0.08 moles) of 4,4′-oxydiphthalic dianhydride and 10.44 g (0.02 moles) of 10BTA was changed to 0.10 moles of 4,4′-oxydiphthalic dianhydride. The resulting polyamide resin has a 2-(methacryloyloxy)ethoxycarbonyl group, which is a radically polymerizable group. The resulting polyamide resin had a polystyrene-equivalent weight average molecular weight of 50,000 as measured by gel permeation chromatography. A resin film-forming composition was obtained and evaluated for dielectric loss tangent and elongation as in Example 1. As a result, the resin film was evaluated as “X” for dielectric loss tangent, as “O” for elongation, and as “O” for strength.

### Example 11

### (Production of Polyamide Macromonomer)

In 100 g of N-methyl-2-pyrrolidone (NMP) was dispersed 52.22 g (0.10 moles) of 10BTA. To the resulting solution were added 26.03 g (0.20 moles) of 2-hydroxyethyl methacrylate (HEMA), 15.82 g (0.20 moles) of pyridine, and 2.443 g (0.02 moles) of dimethylaminopyridine, and then stirred at room temperature for 16 hours to produce di-2-methacryloyloxyethyl ester of tetracarboxylic acid derived from 10BTA. The resulting dicarboxylic acid solution containing 0.1 moles of the diester was cooled to 0° C. Subsequently, a solution including 42.30 g (0.21 moles) of dicyclohexylcarbodiimide and 42 g of NMP, 43.33 g (0.21 moles) of 1-hydroxybenzotriazole monohydrate, and a diamine solution including 26.63 g (0.133 moles) of DA1 and 60 g of NMP were added dropwise into the dicarboxylic acid solution. After the dropwise addition was completed, the resulting reactive liquid was stirred at room temperature for 2 hours to undergo condensation reaction. After the condensation reaction, the resulting precipitate was filtered so that a solution of a polyamide macromonomer having amino end groups was obtained. The resulting polyamide macromonomer had a polystyrene-equivalent weight average molecular weight of 8,000 as measured by gel permeation chromatography.

### (Production of Block Copolymer)

In 300 g of NMP was dispersed 124.1 g (0.4 moles) of 4,4′-oxydiphthalic anhydride. To the resulting dispersion were added 109.3 g (0.84 moles) of 2-hydroxyethyl methacrylate and 66.44 g (0.84 moles) of pyridine. The dispersion was then stirred at room temperature for 14 hours to produce a solution of a dicarboxylic acid having two 2-(2-methacryloyloxy)ethoxycarbonyl groups, which resulted from the reaction of 4,4′-oxydiphthalic anhydride with 2-hydroxyethyl methacrylate. The resulting dicarboxylic acid solution was cooled with ice. To the cooled solution were added 128.6 g (0.84 moles) of 1-hydroxybenzotriazole monohydrate and 173.3 g (0.84 moles) of DCC, and the resulting solution was cooled with ice and stirred for 30 minutes. Subsequently, the polyamide macromonomer solution previously obtained and a solution of 73.42 g (0.37 moles) of DA1 in 200 g of NMP were added to the solution containing the dicarboxylic acid, 1-hydroxybenzotriazole monohydrate, and DCC. The resulting mixture was stirred at room temperature for 6 hours. Subsequently, 60.0 g of methanol was added to the mixture and stirred to form a precipitate. The precipitate was removed by filtration, and the resulting filtrate was added dropwise into an isopropyl alcohol aqueous solution to precipitate a resin. The resulting resin was washed three times with isopropyl alcohol to give a polyamide resin resulting from the copolymerization with the polyamide macromonomer. As a result of analysis by gel permeation chromatography, the resulting polyamide resin was found to have a weight average molecular weight of 40,000. The resulting chart was unimodal, and it was confirmed that the polyamide resin resulted from the copolymerization with the polyamide macromonomer.

A resin film-forming composition was obtained as in Example 1 using the resulting block copolymer including a block derived from the polyamide macromonomer. The resulting resin film-forming composition was used to form a resin film as in Example 1. The resulting resin film was evaluated for dielectric loss tangent, elongation, and strength as in Example 1. As a result, the dielectric loss tangent, elongation, and strength of the resin film were all evaluated as “O”.

### Example 12

A resin film-forming composition was obtained as in Example 11 except that 52.22 g (0.10 moles) of 10BTA for the production of the polyamide macromonomer was changed to 0.10 moles of 4,4′-oxydiphthalic anhydride and 26.63 g (0.133 moles) of DA1 for the production of the polyamide macromonomer was changed to 0.133 moles of DA6. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. As a result, the dielectric loss tangent, elongation, and strength of the resin film were all evaluated as “O”.

### Example 13

A resin film-forming composition was obtained as in Example 11 except that 26.63 g (0.133 moles) of DA1 for the production of the polyamide macromonomer was changed to 0.133 moles of DA2 and 73.42 g (0.37 moles) of DA1 for the production of the block copolymer was changed to 0.37 moles of DA2. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 14

A resin film-forming composition was obtained as in Example 11 except that 52.22 g (0.10 moles) of 10BTA for the production of the polyamide macromonomer was changed to 0.10 moles of 4,4′-oxydiphthalic anhydride, 26.63 g (0.133 moles) of DA1 for the production of the polyamide macromonomer was changed to 0.133 moles of DA6, and 73.42 g (0.37 moles) of DA1 for the production of the block copolymer was changed to 0.37 moles of DA2. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 15

A resin film-forming composition was obtained as in Example 11 except that 124.1 g (0.4 moles) of 4,4′-oxydiphthalic anhydride for the production of the block copolymer was changed to 0.4 moles of 3,3′,4,4′-biphenyltetracarboxylic dianhydride. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 16

A resin film-forming composition was obtained as in Example 11 except that 26.63 g (0.133 moles) of DA1 for the production of the polyamide macromonomer was changed to 0.133 moles of DA6 and 124.1 g (0.4 moles) of 4,4′-oxydiphthalic anhydride for the production of the block copolymer was changed to 0.4 moles of 3,3′,4,4′-biphenyltetracarboxylic dianhydride. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 17

A resin film-forming composition was obtained as in Example 11 except that 26.63 g (0.133 moles) of DA1 for the production of the polyamide macromonomer was changed to 0.133 moles of DA3, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA3. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 18

A resin film-forming composition was obtained as in Example 11 except that 52.22 g (0.10 moles) of 10BTA for the production of the polyamide macromonomer was changed to 0.10 moles of 4,4′-oxydiphthalic anhydride, 26.63 g (0.133 moles) of DA1 for the production of the polyamide macromonomer was changed to 0.133 moles of DA6, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA3. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 19

A resin film-forming composition was obtained as in Example 11 except that 26.63 g (0.133 moles) of DA1 for the production of the polyamide macromonomer was changed to 0.133 moles of DA5, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA3. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 20

A resin film-forming composition was obtained as in Example 11 except that 52.22 g (0.10 moles) of 10BTA for the production of the polyamide macromonomer was changed to 0.10 moles of 2,2-bis[4-(3,4-dicarboxyphenyloxy)phenyl]propane dianhydride, 26.63 g (0.133 moles) of DA1 for the production of the polyamide macromonomer was changed to 0.133 moles of DA5, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA3. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 21

A resin film-forming composition was obtained as in Example 11 except that 52.22 g (0.10 moles) of 10BTA for the production of the polyamide macromonomer was changed to 0.10 moles of 4,4′-oxydiphthalic anhydride, 26.63 g (0.133 moles) of DA1 for the production of the polyamide macromonomer was changed to 0.133 moles of DA6, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA4. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 22

A resin film-forming composition was obtained as in Example 11 except that 26.63 g (0.133 moles) for the production of the polyamide macromonomer was changed to 0.133 moles of DA6, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA4. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 23

A resin film-forming composition was obtained as in Example 11 except that 26.63 g (0.133 moles) of DA1 for the production of the polyamide macromonomer was changed to 0.133 moles of DA5, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA4. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 24

A resin film-forming composition was obtained as in Example 11 except that 52.22 g (0.10 moles) of 10BTA for the production of the polyamide macromonomer was changed to 0.10 moles of 2,2-bis[4-(3,4-dicarboxyphenyloxy)phenyl]propane dianhydride, 73.42 g (0.37 moles) of DA1 for the production of the polyamide macromonomer was changed to 0.37 moles of DA5, 124.1 g (0.4 moles) of 4,4′-oxydiphthalic anhydride for the production of the block copolymer was changed to 0.4 moles of 3,3′,4,4′-biphenyltetracarboxylic dianhydride, and 73.42 g (0.37 moles) of DA1 for the production of the block copolymer was changed to 0.37 moles of DA4. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 25

A resin film-forming composition was obtained as in Example 11 except that the amount of DA1 for the production of the polyamide macromonomer was changed from 0.133 moles to 0.118 moles and the amount of DA1 for the production of the block copolymer was changed from 0.37 moles to 0.382 moles. The polyamide macromonomer used for the production of the block copolymer had a polystyrene-equivalent weight average molecular weight of 25,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 26

A resin film-forming composition was obtained as in Example 11 except that the amount of DA1 for the production of the polyamide macromonomer was changed from 0.133 moles to 0.167 moles and the amount of DA1 for the production of the block copolymer was changed from 0.37 moles to 0.333 moles. The polyamide macromonomer used for the production of the block copolymer had a polystyrene-equivalent weight average molecular weight of 3,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 27

### (Production of Polyamide Macromonomer)

In 100 g of N-methyl-2-pyrrolidone (NMP) was dispersed 52.22 g (0.10 moles) of 10BTA. To the resulting solution were added 26.03 g (0.20 moles) of 2-hydroxyethyl methacrylate (HEMA), 15.82 g (0.20 moles) of pyridine, and 2.443 g (0.02 moles) of dimethylaminopyridine, and stirred at room temperature for 16 hours to produce di-2-methacryloyloxyethyl ester of tetracarboxylic acid derived from 10BTA. The resulting dicarboxylic acid solution containing 0.1 moles of the diester was cooled to 0° C. Subsequently, a solution including 42.30 g (0.21 moles) of dicyclohexylcarbodiimide and 42 g of NMP, 43.33 g (0.21 moles) of 1-hydroxybenzotriazole monohydrate, and a diamine solution including 15.02 g (0.075 moles) of DA1 and 60 g of NMP were added dropwise into the dicarboxylic acid solution. After the dropwise addition was completed, the resulting reactive liquid was stirred at room temperature for 2 hours to undergo condensation reaction. After the condensation reaction, the resulting precipitate was filtered so that a solution of a polyamide macromonomer having carboxy end groups was obtained. The resulting polyamide macromonomer had a polystyrene-equivalent weight average molecular weight of 8,000 as measured by gel permeation chromatography.

### (Production of Block Copolymer)

In 300 g of NMP was dispersed 85.31 g (0.275 moles) of 4,4′-oxydiphthalic anhydride. To the resulting dispersion were added 75.16 g (0.578 moles) of 2-hydroxyethyl methacrylate and 45.68 g (0.578 moles) of pyridine. The dispersion was then stirred at room temperature for 14 hours to produce a solution of a dicarboxylic acid having two 2-(2-methacryloyloxy)ethoxycarbonyl groups, which resulted from the reaction of 4,4′-oxydiphthalic anhydride with 2-hydroxyethyl methacrylate. The resulting dicarboxylic acid solution was cooled with ice. To the cooled solution were added 88.4 g (0.578 moles) of 1-hydroxybenzotriazole monohydrate and 119.2 g (0.578 moles) of DCC, and the resulting solution was cooled with ice and stirred for 30 minutes. Subsequently, the polyamide macromonomer solution previously obtained and a solution of 60.07 g (0.30 moles) of DA1 in 200 g of NMP were added to the solution containing the dicarboxylic acid, 1-hydroxybenzotriazole monohydrate, and DCC. The resulting mixture was stirred at room temperature for 6 hours. Subsequently, 60.0 g of methanol was added to the mixture and stirred to form a precipitate. The precipitate was removed by filtration, and the resulting filtrate was added dropwise into an isopropyl alcohol aqueous solution to precipitate a resin. The resulting resin was washed three times with isopropyl alcohol to give a polyamide resin resulting from the copolymerization with the polyamide macromonomer. As a result of analysis by gel permeation chromatography, the polyamide resin resulting from the copolymerization with the polyamide macromonomer having carboxy end groups was found to have a weight average molecular weight of 40,000. The resulting chart was unimodal, and it was confirmed that the polyamide macromonomer had undergone copolymerization.

A resin film-forming composition was obtained as in Example 1 using the resulting block copolymer including a block derived from the polyamide macromonomer. The resulting resin film-forming composition was used to form a resin film as in Example 1. The resulting resin film was evaluated for dielectric loss tangent, elongation, and strength as in Example 1. As a result, the dielectric loss tangent, elongation, and strength of the resin film were all evaluated as “O”.

### Example 28

A resin film-forming composition was obtained as in Example 27 except that 15.02 g (0.075 moles) of DA1 for the production of the polyamide macromonomer was changed to 0.075 moles of DA3, 85.31 g (0.275 moles) of 4,4′-oxydiphthalic anhydride for the production of the block copolymer was changed to 0.275 moles of 3,3′,4,4′-biphenyltetracarboxylic dianhydride, and 60.07 g (0.30 moles) of DA1 for the production of the block copolymer was changed to 0.30 moles of DA3. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

### Example 29

A resin film-forming composition was obtained as in Example 27 except that 15.02 g (0.075 moles) of DA1 for the production of the polyamide macromonomer was changed to 0.075 moles of DA5, 85.31 g (0.275 moles) of 4,4′-oxydiphthalic anhydride for the production of the block copolymers was changed to 0.275 moles of 3,3′,4,4′-biphenyltetracarboxylic dianhydride, and 60.07 g (0.30 moles) of DA1 for the production of the block copolymer was changed to 0.30 moles of DA4. The polyamide macromonomer used for the production of the block copolymer had a polystyrene-equivalent weight average molecular weight of 8,000 as measured by gel permeation chromatography. As a result of analysis by gel permeation chromatography, the polyamide resin resulting from the copolymerization with the polyamide macromonomer was found to have a weight average molecular weight of 40,000. The resulting resin film-forming composition was evaluated for dielectric loss tangent, elongation, and strength as in Example 1. The block copolymer in the resin film was found to contain a block derived from the polyamide macromonomer. As a result, the dielectric loss tangent, elongation, and strength of the resin film were all evaluated as “O”.

The resulting resin film-forming compositions of Examples 1 to 29 were each applied by a spin coater onto a silicon wafer with a copper film formed thereon by sputtering. The composition film was then baked at 80° C. for 300 seconds to form a 12 μm-thick coating film. The coating film was exposed to 2,000 mJ/cm² of light from a ghi line exposure system (manufactured by Ultratech, Inc.) (Focus 0 μm) through a negative mask for allowing the formation of via holes with an aperture of 50 μm. The exposed coating film was developed by being immersed in cyclopentanone for 120 seconds to form a patterned resin film with 50 μm via holes. In an inert oven, the resulting resin film was heated under a nitrogen atmosphere to 230° C. at a rate of temperature increase of 5° C./minute and then heated at 230° C. for 1 hour. When the temperature dropped to 100° C., the wafer was removed. As a result, a patterned imidized resin film was obtained on the substrate.

1. A block copolymer comprising a copolymer resulting from copolymerization of:
a polyamide macromonomer and/or a polyimide macromonomer;
a tetracarboxylic dianhydride and/or a dicarboxylic acid resulting from reaction of a tetracarboxylic dianhydride with an alcohol; and
a diamine compound, the block copolymer comprising a block derived from the polyamide macromonomer; and/or a block derived from the polyimide macromonomer,
wherein the polyamide macromonomer a macromonomer resulting from polymerization of a diamine compound and a dicarboxylic acid resulting from reaction of a tetracarboxylic dianhydride with an alcohol,
wherein the polyimide macromonomer is a polyamic acid macromonomer resulting from polymerization of a tetracarboxylic dianhydride and a diamine compound or a macromonomer resulting from imidization of the polyamide macromonomer,
wherein the polyamide macromonomer and the polyimide macromonomer each have a weight average molecular weight of 1,500 or more and 30,000 or less.

2. The block copolymer according to claim 1,
wherein the diamine compound polymerized with the macromonomer includes one or more selected from the group consisting of:
a diamine compound (A-1) of Formula (A1): 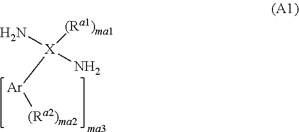
wherein X is an organic group having 1 or more and 100 or less carbon atoms, R^{a1} is a hydroxy group, a carboxy group, or a halogen atom, R^{a2} is an aliphatic group having 1 or more and 20 or less carbon atoms, a hydroxy group, a carboxy group, a sulfonic acid group, or a halogen atom, Ar is a phenyl group optionally substituted with R^{a2} or a naphthyl group optionally substituted with R^{a2}, ma1 is an integer of 0 or more and 10 or less, ma2 is an integer of 0 or more and 7 or less, and ma3 is an integer of 1 or more and 10 or less;
a diamine compound (A-2) having a partial structure of Formula (A2): 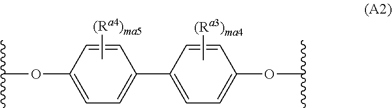
wherein R^{a3} and R^{a4} are each independently an alkyl group having 1 or more and 4 or less carbon atoms, an alkoxy group having 1 or more and 4 or less carbon atoms, or a halogen atom, and ma4 and ma5 are each independently an integer of 0 or more and 4 or less, and
not corresponding to the diamine compound (A-1);
a diamine compound (A-3) having a partial structure of Formula (A3): 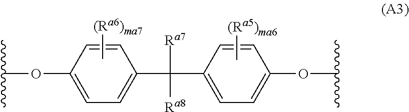
wherein R^{a5} and R^{a6} are each independently an alkyl group having 1 or more and 4 or less carbon atoms, an alkoxy group having 1 or more and 4 or less carbon atoms, or a halogen atom, ma6 and ma7 are each independently an integer of 0 or more and 4 or less, R^{a7} and R^{a8} are each independently a hydrogen atom, an alkyl group having 1 or more and 4 or less carbon atoms, a halogenated alkyl group having 1 or more and 4 or less carbon atoms, or a phenyl group, and R^{a7} and R^{a8} may be bonded to each other to form a ring, and
not corresponding to the diamine compound (A-1) or the diamine compound (A-2); and
a dimer diamine compound (A⁴).

3. The block copolymer according to claim 1, wherein the block copolymer contains an alkylene group having 2 or more and 50 or less carbon atoms.

4. The block copolymer according to claim 1,
wherein the macromonomer is the polyamide macromonomer, and
wherein the polyamide macromonomer is a polymer resulting from polymerization of a diamine compound and a dicarboxylic acid resulting from reaction of a tetracarboxylic dianhydride with a radically polymerizable group-containing alcohol.

5. A polyimide resin comprising a product resulting from imidization of the block copolymer according to claim 1.

6. A resin film-forming composition comprising: a resin (A); and a solvent (S), the resin (A) comprising the block copolymer according to claim 1 and/or the polyimide resin comprising a product resulting from imidization of the block copolymer according to claim 1.

7. The resin film-forming composition according to claim 6, wherein the resin (A) comprises a block copolymer comprising a copolymer resulting from copolymerization of:
a polyamide macromonomer and/or a polyimide macromonomer;
a tetracarboxylic dianhydride and/or a dicarboxylic acid resulting from reaction of a tetracarboxylic dianhydride with an alcohol; and
a diamine compound, the block copolymer comprising a block derived from the polyamide macromonomer; and/or a block derived from the polyimide macromonomer,
wherein the polyamide macromonomer a macromonomer resulting from polymerization of a diamine compound and a dicarboxylic acid resulting from reaction of a tetracarboxylic dianhydride with an alcohol,
wherein the polyimide macromonomer is a polyamic acid macromonomer resulting from polymerization of a tetracarboxylic dianhydride and a diamine compound or a macromonomer resulting from imidization of the polyamide macromonomer,
wherein the polyamide macromonomer and the polyimide macromonomer each have a weight average molecular weight of 1,500 or more and 30,000 or less,
wherein the macromonomer is the polyamide macromonomer, and
wherein the polyamide macromonomer is a polymer resulting from polymerization of a diamine compound and a dicarboxylic acid resulting from reaction of a tetracarboxylic dianhydride with a radically polymerizable group-containing alcohol,
and wherein the resin film-forming composition further comprises a photo-radical polymerization initiator (C).

8. A resin film forming method comprising:
applying the resin film-forming composition according to claim 6 onto a substrate to form a coating; and
drying the coating to form a resin film.

9. A method of forming a patterned resin film, the method comprising:
applying the resin film-forming composition according to claim 7 onto a substrate to form a coating;
subjecting the coating to positionally selective exposure to an active ray or a radiation; and
developing the exposed coating to form a patterned resin film.

10. The method according to claim 9, wherein the method further comprises heating the patterned resin film to imidize the patterned resin film.
